(19) United States
(12) Patent Application Publication
(10) Pub. No.: US 2026/0371675 A1
(43) Pub. Date: Nov. 19, 2026

(54) SEMICONDUCTOR DEVICE

(71) Applicant: ROHM CO., LTD., Kyoto-shi (JP)

(72) Inventor: Seigo MORI, Kyoto-shi (JP)

(73) Assignee: ROHM CO., LTD., Kyoto-shi (JP)

(21) Appl. No.: 19/745,086

(22) Filed: Jul. 17, 2026

Related U.S. Application Data
(63) Continuation of application No. PCT/JP2025/001092, filed on Jan. 16, 2025.

(30) Foreign Application Priority Data
Jan. 26, 2024 (JP) 2024-009955

(51) Int. Cl. H10D 62/60; H10D 8/60; H10D 30/01; H10D 30/66; H10D 62/10; H10D 62/815; H10D 62/832; H10D 62/834; H10D 64/00; H10D 64/27

(52) U.S. Cl. CPC H10D 62/60; H10D 30/665; H10D 30/668; H10D 62/102; H10D 62/126; H10D 62/8171; H10D 62/8325; H10D 62/834; H10D 64/518; H10D 8/60; H10D 30/0291; H10D 64/112; H10D 64/117

(57) ABSTRACT

A semiconductor device includes a semiconductor layer of a first conductivity type that has a first principal surface and a second principal surface, a first pillar region of the first conductivity type that extends in a depth direction of the semiconductor layer from the first principal surface toward the second principal surface inside the semiconductor layer, and a second pillar region of a second conductivity type that is adjacent to the first pillar region inside the semiconductor layer and extends in the depth direction, in which in the depth direction, a maximum value of a profile of a background impurity concentration of the first conductivity type of the second pillar region is not more than 1/2 of a maximum value of a profile of a first impurity concentration of the first conductivity type of the first pillar region.

### CROSS-REFERENCE TO RELATED APPLICATIONS

The present application is a bypass continuation application of International Patent Application No. PCT/JP2025/001092, filed on Jan. 16, 2025, which claims priority to Japanese Patent Application No. 2024-009955, filed on Jan. 26, 2024 with the Japan Patent Office, and the entire disclosure of the above applications are incorporated herein by reference.

### TECHNICAL FIELD

The present disclosure relates to a semiconductor device.

### BACKGROUND ART

Patent Literature 1 (US 2015/0028351 A1 Specification) discloses an electronic device having an impurity region introduced into a silicon carbide layer by a channeling implantation method.

### BRIEF DESCRIPTION OF DRAWINGS

FIG. 1 is a plan view showing a semiconductor device according to a first preferred embodiment.

FIG. 2 is a sectional view taken along line II-II shown in FIG. 1.

FIG. 3 is a plan view showing a layout example of a chip.

FIG. 4 is a perspective view showing the layout example of the chip.

FIG. 5 is a sectional perspective view showing a principal portion of the chip together with a basic embodiment of a pillar region.

FIG. 6 is a profile showing an example of concentration gradients of a drift region, a first pillar region, and a second pillar region.

FIG. 7 is a profile showing a reference example of the concentration gradients of the drift region, the first pillar region, and the second pillar region.

FIG. 8 is a diagram showing a charge balance distribution in a depth direction of a super junction structure.

FIG. 9 is a sectional perspective view showing the pillar region according to a first configuration example.

FIG. 10 is a sectional perspective view showing the pillar region according to a second configuration example.

FIG. 11 is a sectional perspective view showing the pillar region according to a third configuration example.

FIG. 12 is a sectional perspective view showing the pillar region according to a fourth configuration example.

FIG. 13 is a sectional perspective view showing the pillar region according to a fifth configuration example.

FIG. 14 is a sectional perspective view showing the pillar region according to a sixth configuration example.

FIG. 15 is a sectional perspective view showing the pillar region according to a seventh configuration example.

FIG. 16 is a sectional perspective view showing the pillar region according to an eighth configuration example.

FIG. 17 is a sectional perspective view showing the pillar region according to a ninth configuration example.

FIG. 18 is a sectional perspective view showing the pillar region according to a tenth configuration example.

FIG. 19 is a sectional perspective view showing the pillar region according to an eleventh configuration example.

FIG. 20 is a plan view showing a principal portion of an active region.

FIG. 21 is a sectional perspective view showing a gate structure according to the first configuration example.

FIG. 22 is a sectional view showing a principal portion of an outer peripheral region.

FIG. 23 is a schematic view showing a wafer used in manufacture of the semiconductor device.

FIG. 24 is a flowchart showing a manufacturing method example of the semiconductor device.

FIGS. 25A to 25D are sectional perspective views showing the manufacturing method example of the semiconductor device.

FIG. 26 is a plan view showing a semiconductor device according to a second preferred embodiment.

FIG. 27 is a sectional view taken along line XXVII-XXVII shown in FIG. 26.

FIG. 28 is a plan view showing the layout example of the chip.

FIG. 29 is a perspective view showing the layout example of the chip.

FIG. 30 is a plan view showing a principal portion of the active region.

FIG. 31 is a sectional perspective view showing the gate structure according to the first configuration example.

FIG. 32 is a sectional view showing a principal portion of the outer peripheral region.

FIG. 33 is a sectional perspective view showing the gate structure according to the second configuration example.

FIG. 34 is a sectional perspective view showing the gate structure according to the third configuration example.

FIG. 35 is a sectional perspective view showing the gate structure according to the fourth configuration example.

FIG. 36 is a plan view showing a semiconductor device according to a third preferred embodiment.

FIG. 37 is a sectional view taken along line XXXVII-XXXVII shown in FIG. 36.

FIG. 38 is a plan view showing the layout example of the chip.

FIG. 39 is a perspective view showing the layout example of the chip.

FIG. 40 is a sectional perspective view showing a diode structure according to the basic embodiment.

### DETAILED DESCRIPTION

Hereinafter, preferred embodiments shall be described in detail with reference to attached drawings. The attached drawings are all schematic views and are not strictly illustrated, and scales, proportions, angles and the like thereof do not always match. Identical reference signs are given to corresponding structures among the attached drawings, and duplicate descriptions thereof shall be omitted or simplified. For the structures whose description has been omitted or simplified, the description given before the omission or simplification shall apply.

When the wording “substantially equal” is used in this description, the wording includes a numerical value (shape) equal to a numerical value (shape) of a comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type,” the “p-type” may be referred to as a “first conductivity type,” and the “n-type” may be referred to as a “second conductivity type.” As a matter of course, the “n-type” may be referred to as the “first conductivity type,” and the “p-type” may be referred to as the “second conductivity type” instead. The “p-type” is a conductivity type due to a trivalent element and the “n-type” is a conductivity type due to a pentavalent element. Unless noted in particular otherwise, the trivalent element is at least one type among boron, aluminum, gallium, and indium. Unless noted in particular otherwise, the pentavalent element is at least one type among nitrogen, phosphorus, arsenic, antimony, and bismuth.

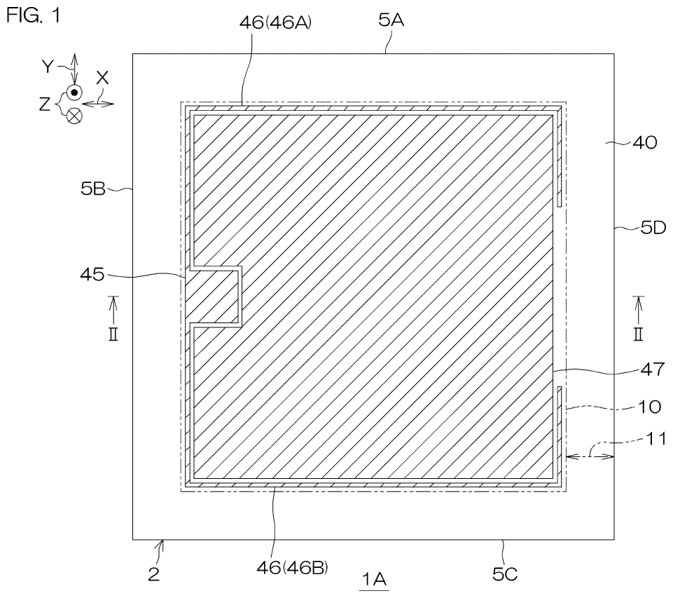

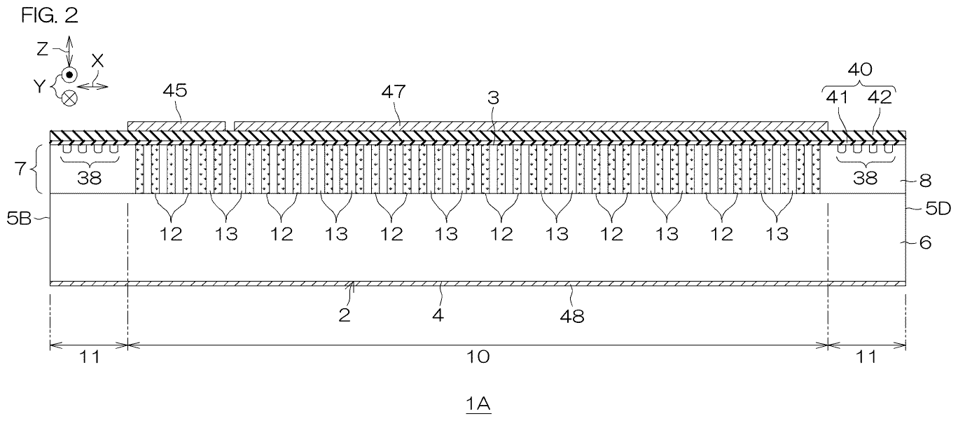

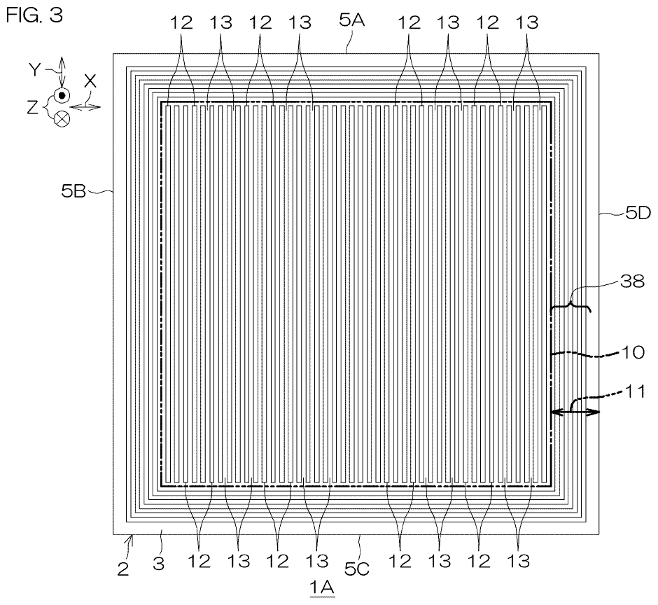

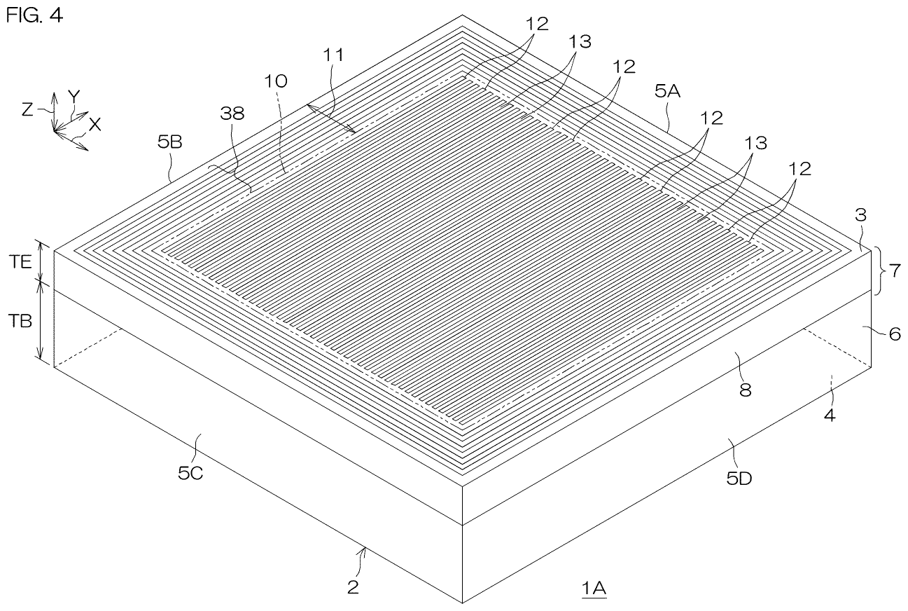

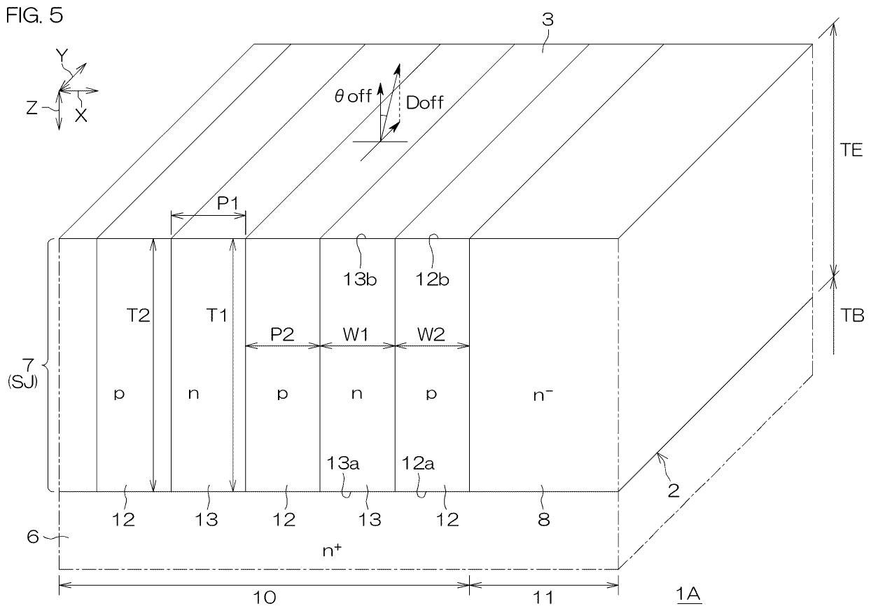

FIG. 1 is a plan view showing a semiconductor device 1A according to a first preferred embodiment. FIG. 2 is a sectional view taken along line II-II shown in FIG. 1. FIG. 3 is a plan view showing a layout example of a chip 2. FIG. 4 is a perspective view showing the layout example of the chip 2. FIG. 5 is a sectional perspective view showing a principal portion of the chip 2 together with a basic embodiment of a second pillar region 12.

Referring to FIGS. 1 to 5, the semiconductor device 1A is an SiC semiconductor device in this embodiment. The semiconductor device 1A includes the chip 2 containing an SiC monocrystal. The chip 2 may be referred to as an “SiC chip” or a “semiconductor chip.” In this embodiment, the chip 2 is constituted of the SiC monocrystal, which is a hexagonal crystal, and is formed in a rectangular parallelepiped shape. The SiC monocrystal that is a hexagonal crystal has multiple polytypes including a 2H (hexagonal)-SiC monocrystal, a 4H—SiC monocrystal, a 6H—SiC monocrystal, etc. In this embodiment, an example in which the chip 2 is constituted of the 4H—SiC monocrystal is to be given, but the chip 2 may be constituted of another polytype instead.

The chip 2 has a first principal surface 3 on one side, a second principal surface 4 on the other side, and first to fourth side surfaces 5A to 5D connecting the first principal surface 3 and the second principal surface 4. In a plan view as viewed from a vertical direction Z (hereinafter referred to simply as “plan view”), the first principal surface 3 and the second principal surface 4 are formed in quadrilateral shapes. The vertical direction Z is also a thickness direction of the chip 2 and a normal direction to the first principal surface 3 (the second principal surface 4). The first principal surface 3 and the second principal surface 4 may be formed in a square shape or a rectangular shape in plan view.

The first principal surface 3 and the second principal surface 4 are preferably formed by c-planes of the SiC monocrystal. In this case, preferably, the first principal surface 3 is formed by a silicon plane (a (0001) plane) of the SiC monocrystal and the second principal surface 4 is formed by a carbon plane (a (000-1) plane) of the SiC monocrystal.

In regard to a circumferential direction of the chip 2 with the first side surface 5A as a starting point (counterclockwise in FIG. 1), the second side surface 5B is connected to the first side surface 5A, the third side surface 5C is connected to the second side surface 5B, and the fourth side surface 5D is connected to the first side surface 5A and the third side surface 5C. The first side surface 5A and the third side surface 5C extend in a first direction X oriented along the first principal surface 3 and are opposed in a second direction Y intersecting (specifically, orthogonal to) the first direction X. The second side surface 5B and the fourth side surface 5D extend in the second direction Y and are opposed in the first direction X.

In this embodiment, the first direction X is an m-axis direction (a [1-100] direction) of the SiC monocrystal and the second direction Y is an a-axis direction (a [11-20] direction) of the SiC monocrystal. As a matter of course, the first direction X may instead be the a-axis direction of the SiC monocrystal and the second direction Y may instead be the m-axis direction of the SiC monocrystal.

An XY plane that includes the first direction X and the second direction Y forms a horizontal plane that is orthogonal to the vertical direction Z. In the following, an axis extending along the vertical direction Z is expressed at times as a “vertical axis.” Also, in the following, the first direction X and the second direction Y is expressed at times as “horizontal directions.” Horizontal directions are also directions that extend along the first principal surface 3.

With reference to FIG. 5, the chip 2 (the first principal surface 3 and the second principal surface 4) has an off angle θoff inclined at a predetermined angle in a predetermined off direction Doff with respect to the c-plane of the SiC monocrystal. That is, a c-axis (a (0001) axis) of the SiC monocrystal is inclined by just the off angle θoff toward the off direction Doff from the vertical axis. Also, the c-plane of the SiC monocrystal is inclined by just the off angle θoff with respect to the horizontal plane.

The off direction Doff is preferably the a-axis direction (that is, the second direction Y) of the SiC monocrystal. The off angle θoff may exceed 0° and be not more than 10°. The off angle θoff may have a value belonging to any one range among exceeding 0° and not more than 1°, exceeding 1° and not more than 2.5°, exceeding 2.5° and not more than 5°, exceeding 5° and not more than 7.5°, and exceeding 7.5° and not more than 10°.

The off angle θoff is preferably not more than 5°. The off angle θoff is particularly preferably not less than 2° and not more than 4.5°. The off angle θoff is typically set in a range of 4°±0.1°. As a matter of course, this Description does not exclude an embodiment in which the off angle θoff is 0° (that is, an embodiment in which the first principal surface 3 is a just surface with respect to the c-plane).

The chip 2 includes a base layer 6 of an n-type that is constituted of an SiC monocrystal. The base layer 6 may be referred to as a “base SiC layer,” a “base region,” etc. The base layer 6 extends in a layered shape in the horizontal directions and forms the second principal surface 4 and portions of the first to fourth side surfaces 5A to 5D. In this embodiment, the base layer 6 is constituted of a substrate made of the SiC monocrystal (in other words, an SiC substrate). The base layer 6 has the off direction Doff and the off angle θoff described above.

The base layer 6 may have an n-type impurity concentration of not less than 1×10¹⁸ cm⁻³ and not more than 1×10²¹ cm⁻³ as a peak value. The base layer 6 preferably has an n-type impurity concentration that is substantially fixed in a thickness direction. The n-type impurity concentration of the base layer 6 is preferably adjusted by a single type of pentavalent element. The n-type impurity concentration of the base layer 6 is particularly preferably adjusted by a pentavalent element other than phosphorus. In this embodiment, the n-type impurity concentration of the base layer 6 is adjusted by nitrogen.

The base layer 6 has a base thickness TB. The base thickness TB may be not less than 5 μm and not more than 300 μm. The base thickness TB may have a value belonging to any one range among not less than 5 μm and not more than 50 μm, exceeding 50 μm and not more than 100 μm, exceeding 100 μm and not more than 150 μm, exceeding 150 μm and not more than 200 μm, exceeding 200 μm and not more than 250 μm, and exceeding 250 μm and not more than 300 μm. The base thickness TB is preferably not less than 50 μm and not more than 250 μm.

The chip 2 includes a laminated portion 7 laminated on the base layer 6. The laminated portion 7 may be referred to as a “semiconductor layer,” an “SiC layer,” an “SiC laminated portion,” a “semiconductor laminated portion,” or the like. In this embodiment, the laminated portion 7 is provided as a formation layer of a super junction structure SJ. In this embodiment, the laminated portion 7 is formed by a single semiconductor layer, but may be formed by a plurality of semiconductor layers. When the laminated portion 7 is a plurality of semiconductor layers, the number of laminated layers is arbitrary, and is appropriately adjusted according to the electrical characteristics to be achieved. A withstand voltage value (breakdown voltage), a resistance value, and the like can be given as examples of the electrical characteristics.

The laminated portion 7 extends in a layered shape in the horizontal directions and forms portions of the first to fourth side surfaces 5A to 5D of the chip 2. The laminated portion 7 is constituted of an epitaxial layer (that is, an SiC epitaxial layer) formed by crystal growth with the base layer 6 as a starting point.

The laminated portion 7 has a lower end and an upper end. The lower end of the laminated portion 7 is a crystal growth starting point, and the upper end of the laminated portion 7 is a crystal growth end point. The laminated portion 7 is formed by continuous crystal growth from the base layer 6 and therefore, the lower end of the laminated portion 7 coincides with an upper end of the base layer 6. A boundary portion between the base layer 6 and the laminated portion 7 is not necessarily visually recognizable and can be evaluated and/or determined indirectly from other arrangements and elements. The laminated portion 7 has the off direction Doff and the off angle θoff that substantially coincide with the off direction Doff and the off angle θoff of the base layer 6.

The entire laminated portion 7 may be referred to as a drift region 8. The drift region 8 is a region serving as a base of an impurity region (a first pillar region 13, the second pillar region 12, a body region 32, a source region 33, a contact region 34, and the like, which will be described later) selectively formed by implanting impurity ions into the laminated portion 7. By implanting n-type impurity ions or p-type impurity ions into the laminated portion 7 such as to have a concentration exceeding the impurity concentration of the drift region 8, various n-type or p-type impurity regions having characteristics corresponding to the respective concentrations are formed.

The drift region 8 is replaced with various impurity regions in a target region of the laminated portion 7 by ion implantation, but n-type impurity ions added at the time of epitaxial growth of the laminated portion 7 remain at the concentration at the time of growth. As a result, the drift region 8 provides an n-type background concentration within a range not hindering the characteristics (electrical behavior) of the various impurity regions. On the other hand, even if n-type impurity ions or p-type impurity ions are implanted into the laminated portion 7, the characteristics of the drift region 8 are maintained in the region as long as the amount implanted is small, and the drift region 8 remains.

An n-type impurity concentration of the laminated portion 7 (the drift region 8) is preferably less than the n-type impurity concentration of the base layer 6. The laminated portion 7 may have an n-type impurity concentration of not less than 1×10¹⁵ cm⁻³ and not more than 1×10¹⁶ cm⁻³ as a peak value. The n-type impurity concentration of the laminated portion 7 may be substantially fixed in a thickness direction. As a matter of course, the n-type impurity concentration of the laminated portion 7 may have a concentration gradient that increases gradually and/or decreases gradually in a lamination direction (a crystal growth direction).

The laminated portion 7 (the drift region 8) has an n-type impurity concentration adjusted by at least one type of pentavalent element. For example, the n-type impurity concentration of the laminated portion 7 may be adjusted by at least one type among nitrogen, phosphorus, arsenic, antimony, and bismuth. The laminated portion 7 preferably contains a pentavalent element other than phosphorus.

The n-type impurity concentration of the laminated portion 7 (the drift region 8) is preferably adjusted by at least nitrogen. When the laminated portion 7 contains two or more pentavalent elements, the laminated portion 7 preferably contains nitrogen and a pentavalent element other than nitrogen. In this case, the laminated portion 7 preferably contains either or both of arsenic and antimony as a pentavalent element other than phosphorus and nitrogen. In this embodiment, the laminated portion 7 (the drift region 8) does not contain phosphorus and contains nitrogen as a pentavalent element.

The laminated portion 7 has an epi thickness TE. The epi thickness TE is preferably less than the base thickness TB. The epi thickness TE is preferably not less than 1 μm. The epi thickness TE is preferably not more than 5 μm. The epi thickness TE may have a value belonging to any one range among not less than 1 μm and not more than 1.5 μm, exceeding 1.5 μm and not more than 2 μm, exceeding 2 μm and not more than 2.5 μm, exceeding 2.5 μm and not more than 3 μm, exceeding 3 μm and not more than 3.5 μm, exceeding 3.5 μm and not more than 4 μm, exceeding 4 μm and not more than 4.5 μm, and exceeding 4.5 μm and not more than 5 μm.

The semiconductor device 1A includes an active region 10 set in the chip 2. The active region 10 is set in an inner portion of the chip 2 at intervals from peripheral edges (the first to fourth side surfaces 5A to 5D) of the chip 2 in plan view. The active region 10 is set in a polygonal shape (in this embodiment, a quadrilateral shape) having four sides parallel to the peripheral edges of the chip 2 in plan view. A planar area of the active region 10 is preferably not less than 50% and not more than 90% of a planar area of the first principal surface 3.

The semiconductor device 1A includes an outer peripheral region 11 that, in the chip 2, is set outside the active region 10. The outer peripheral region 11 is provided in a region between the peripheral edges of the chip 2 and the active region 10 in plan view. The outer peripheral region 11 extends in a band shape along the active region 10 and is set to a polygonal annular shape (in this embodiment, a quadrilateral annular shape) that surrounds the active region 10 in plan view.

The semiconductor device 1A includes a plurality of the second pillar regions 12 of the p-type formed in the laminated portion 7 in the active region 10. The second pillar region 12 may be referred to as a “pillar layer,” a “column layer (region),” a “p-type layer (region),” a “p-type zone,” or the like. The plurality of second pillar regions 12 are formed at intervals in the horizontal direction inside the laminated portion 7, and demarcate a plurality of the first pillar regions 13 of the n-type each formed by a portion of the laminated portion 7.

The plurality of second pillar regions 12 are formed by a portion of the laminated portion 7. The plurality of second pillar regions 12 form a plurality of pn junction portions having a charge balance together with the plurality of first pillar regions 13. As a result, the plurality of second pillar regions 12 form the super junction structure SJ together with the plurality of first pillar regions 13 inside the laminated portion 7. A state of having a charge balance means a state where, for the plurality of second pillar regions 12 that are mutually adjacent, depletion layers spreading from the pn junction portions at one side and depletion layers spreading from the pn junction portions at another side are connected inside the plurality of first pillar regions 13.

The plurality of second pillar regions 12 are aligned at intervals in the first direction X inside the laminated portion 7, and are each formed in a band shape extending in the second direction Y. That is, the plurality of second pillar regions 12 are formed as stripes extending in the second direction Y, and the plurality of first pillar regions 13 are formed as stripes extending in the second direction Y. Also, the plurality of second pillar regions 12 are aligned at intervals in the m-axis direction of the SiC monocrystal and extends in the a-axis direction of the SiC monocrystal. In other words, an extension direction of the plurality of second pillar regions 12 coincides with the off direction Doff of the laminated portion 7.

Referring to FIG. 5, each of the plurality of second pillar regions 12 has a second lower end portion 12a on the lower end side of the laminated portion 7 and a second upper end portion 12b on the upper end side of the laminated portion 7. The second lower end portion 12a is positioned in a region on the lower end side of the laminated portion 7 with respect to an intermediate portion in a thickness range of the laminated portion 7, and the second upper end portion 12b is positioned in a region on the upper end side of the laminated portion 7 with respect to the intermediate portion in the thickness range of the laminated portion 7.

The second lower end portion 12a may be formed at an interval to the upper end side from the lower end of the laminated portion 7, and may face the base layer 6 with a portion (a lower end portion) of the laminated portion 7 interposed therebetween. The second lower end portion 12a may substantially coincide with the lower end of the laminated portion 7 and be connected to the base layer 6.

A distance between the lower end of the laminated portion 7 and the second lower end portion 12a may be not less than 0 μm and not more than 2 μm. The distance between the lower end of the laminated portion 7 and the second lower end portion 12a may have a value belonging to any one range among not less than 0 μm and not more than 0.5 μm, exceeding 0.5 μm and not more than 1 μm, exceeding 1 μm and not more than 1.5 μm, and exceeding 1.5 μm and not more than 2 μm.

The second lower end portion 12a may have an extension portion that crosses the boundary portion between the base layer 6 and the laminated portion 7 and is positioned in the base layer 6. In this case, a thickness of the extension portion of the second lower end portion 12a based on the upper end of the base layer 6 may be exceeding 0 μm and not more than 2 μm. The thickness of the extension portion of the second lower end portion 12a may have a value belonging to any one range among exceeding 0 μm and not more than 0.5 μm, exceeding 0.5 μm and not more than 1 μm, exceeding 1 μm and not more than 1.5 μm, and exceeding 1.5 μm and not more than 2 μm.

The second upper end portion 12b may be formed at an interval to the lower end side from the upper end of the laminated portion 7, and may face the upper end of the laminated portion 7 with a portion (an upper end portion) of the laminated portion 7 interposed therebetween. The second upper end portion 12b may substantially coincide with the upper end of the laminated portion 7.

A distance between the upper end of the laminated portion 7 and the second upper end portion 12b may be not less than 0 μm and not more than 1 μm. The distance between the upper end of the laminated portion 7 and the second upper end portion 12b may have a value belonging to any one range among not less than 0 μm and not more than 0.25 μm, exceeding 0.25 μm and not more than 0.5 μm, exceeding 0.5 μm and not more than 0.75 μm, and exceeding 0.75 μm and not more than 1 μm.

The plurality of second pillar regions 12 may have a p-type impurity concentration of not less than 1×10¹⁵ cm⁻³ and not more than 1×10¹⁸ cm⁻³ as a peak value. The p-type impurity concentration of the second pillar region 12 is preferably adjusted by at least one type of trivalent element. In this embodiment, the p-type impurity concentration of the second pillar region 12 is adjusted by aluminum.

Each of the plurality of second pillar regions 12 has a second width W2. The second width W2 is a width in a direction orthogonal to the extension direction of the second pillar region 12. The second width W2 is preferably less than the epi thickness TE of the laminated portion 7. As a matter of course, the second width W2 may be not less than the epi thickness TE.

The second width W2 may be not less than 0.1 μm and not more than 10 μm. The second width W2 may have a value belonging to any one range among not less than 0.1 μm and not more than 0.25 μm, exceeding 0.25 μm and not more than 0.5 μm, exceeding 0.5 μm and not more than 0.75 μm, exceeding 0.75 μm and not more than 1 μm, exceeding 1 μm and not more than 1.5 μm, exceeding 1.5 μm and not more than 2 μm, exceeding 2 μm and not more than 2.5 μm, exceeding 2.5 μm and not more than 3 μm, exceeding 3 μm and not more than 3.5 μm, exceeding 3.5 μm and not more than 4 μm, exceeding 4 μm and not more than 4.5 μm, exceeding 4.5 μm and not more than 5 μm, exceeding 5 μm and not more than 5.5 μm, exceeding 5.5 μm and not more than 6 μm, exceeding 6 μm and not more than 6.5 μm, exceeding 6.5 μm and not more than 7 μm, exceeding 7 μm and not more than 7.5 μm, exceeding 7.5 μm and not more than 8 μm, exceeding 8 μm and not more than 8.5 μm, exceeding 8.5 μm and not more than 9 μm, exceeding 9 μm and not more than 9.5 μm, and exceeding 9.5 μm and not more than 10 μm. The second width W2 is preferably not less than 0.5 μm and not more than 1.5 μm.

Each of the plurality of second pillar regions 12 has a second thickness T2. The second thickness T2 may be referred to as a depth of the plurality of second pillar regions 12. The second thickness T2 may be less than the epi thickness TE of the laminated portion 7. The second thickness T2 may be greater than the epi thickness TE. The second thickness T2 may be substantially equal to the epi thickness TE.

The second thickness T2 is preferably not less than 1 μm. The second thickness T2 is preferably not more than 30 μm. The second thickness T2 may have a value belonging to any one range among not less than 1 μm and not more than 1.5 μm, exceeding 1.5 μm and not more than 2 μm, exceeding 2 μm and not more than 2.5 μm, exceeding 2.5 μm and not more than 3 μm, exceeding 3 μm and not more than 3.5 μm, exceeding 3.5 μm and not more than 4 μm, exceeding 4 μm and not more than 4.5 μm, exceeding 4.5 μm and not more than 5 μm, exceeding 5 μm and not more than 10 μm, exceeding 10 μm and not more than 15 μm, exceeding 15 μm and not more than 20 μm, exceeding 20 μm and not more than 25 μm, and exceeding 25 μm and not more than 30 μm.

Preferably, the second width W2 is less than the epi thickness TE of the laminated portion 7, and the second thickness T2 is greater than the second width W2. That is, each of the plurality of second pillar regions 12 preferably has a second aspect ratio T2/W2 extending in a vertically long columnar shape along the thickness direction of the laminated portion 7. The second aspect ratio T2/W2 is a ratio of the second thickness T2 to the second width W2. In this case, the second thickness T2 is particularly preferably greater than the epi thickness TE. For example, the second aspect ratio T2/W2 may exceed 1 and be not more than 100.

The plurality of second pillar regions 12 are formed at intervals of a second pitch P2 in the first direction X. The second pitch P2 is preferably less than the epi thickness TE of the laminated portion 7. As a matter of course, the second pitch P2 may be not less than the epi thickness TE.

The second pitch P2 may be not less than 0.1 μm and not more than 10 μm. The second pitch P2 may have a value belonging to any one range among not less than 0.1 μm and not more than 0.25 μm, exceeding 0.25 μm and not more than 0.5 μm, exceeding 0.5 μm and not more than 0.75 μm, exceeding 0.75 μm and not more than 1 μm, exceeding 1 μm and not more than 1.5 μm, exceeding 1.5 μm and not more than 2 μm, exceeding 2 μm and not more than 2.5 μm, exceeding 2.5 μm and not more than 3 μm, exceeding 3 μm and not more than 3.5 μm, exceeding 3.5 μm and not more than 4 μm, exceeding 4 μm and not more than 4.5 μm, exceeding 4.5 μm and not more than 5 μm, exceeding 5 μm and not more than 5.5 μm, exceeding 5.5 μm and not more than 6 μm, exceeding 6 μm and not more than 6.5 μm, exceeding 6.5 μm and not more than 7 μm, exceeding 7 μm and not more than 7.5 μm, exceeding 7.5 μm and not more than 8 μm, exceeding 8 μm and not more than 8.5 μm, exceeding 8.5 μm and not more than 9 μm, exceeding 9 μm and not more than 9.5 μm, and exceeding 9.5 μm and not more than 10 μm. The second pitch P2 is preferably not less than 0.5 μm and not more than 1.5 μm.

Referring to FIG. 5, each of the plurality of first pillar regions 13 has a first lower end portion 13a on the lower end side of the laminated portion 7 and a first upper end portion 13b on the upper end side of the laminated portion 7. The first lower end portion 13a is positioned in the region on the lower end side of the laminated portion 7 with respect to the intermediate portion in the thickness range of the laminated portion 7, and the first upper end portion 13b is positioned in the region on the upper end side of the laminated portion 7 with respect to the intermediate portion in the thickness range of the laminated portion 7.

The first lower end portion 13a may be formed at an interval to the upper end side from the lower end of the laminated portion 7, and may face the base layer 6 with a portion (a lower end portion) of the laminated portion 7 interposed therebetween. The first lower end portion 13a may substantially coincide with the lower end of the laminated portion 7 and be connected to the base layer 6.

A distance between the lower end of the laminated portion 7 and the first lower end portion 13a may be not less than 0 μm and not more than 2 μm. The distance between the lower end of the laminated portion 7 and the first lower end portion 13a may have a value belonging to any one range among not less than 0 μm and not more than 0.5 μm, exceeding 0.5 μm and not more than 1 μm, exceeding 1 μm and not more than 1.5 μm, and exceeding 1.5 μm and not more than 2 μm.

The first lower end portion 13a may have an extension portion that crosses the boundary portion between the base layer 6 and the laminated portion 7 and is positioned in the base layer 6. In this case, a thickness of the extension portion of the first lower end portion 13a based on the upper end of the base layer 6 may be exceeding 0 μm and not more than 2 μm. The thickness of the extension portion of the first lower end portion 13a may have a value belonging to any one range among exceeding 0 μm and not more than 0.5 μm, exceeding 0.5 μm and not more than 1 μm, exceeding 1 μm and not more than 1.5 μm, and exceeding 1.5 μm and not more than 2 μm.

The first upper end portion 13b may be formed at an interval to the lower end side from the upper end of the laminated portion 7, and may face the upper end of the laminated portion 7 with a portion (an upper end portion) of the laminated portion 7 interposed therebetween. The first upper end portion 13b may substantially coincide with the upper end of the laminated portion 7.

A distance between the upper end of the laminated portion 7 and the first upper end portion 13b may be not less than 0 μm and not more than 1 μm. The distance between the upper end of the laminated portion 7 and the first upper end portion 13b may have a value belonging to any one range among not less than 0 μm and not more than 0.25 μm, exceeding 0.25 μm and not more than 0.5 μm, exceeding 0.5 μm and not more than 0.75 μm, and exceeding 0.75 μm and not more than 1 μm.

The plurality of first pillar regions 13 may have an n-type impurity concentration of not less than 1×10¹⁵ cm⁻³ and not more than 1×10¹⁸ cm⁻³ as a peak value. The first pillar region 13 has an n-type impurity concentration adjusted by at least one type of pentavalent element. For example, the n-type impurity concentration of the first pillar region 13 may be adjusted by at least one type among nitrogen, phosphorus, arsenic, antimony, and bismuth. In this embodiment, the n-type impurity concentration of the first pillar region 13 is adjusted by phosphorus.

Each of the plurality of first pillar regions 13 has a first width W1. The first width W1 is a width in a direction orthogonal to an extension direction of the first pillar region 13. The first width W1 is preferably the same as the second width W2. As a matter of course, the first width W1 may be wider than the second width W2 or narrower than the second width W2. The first width W1 is preferably less than the epi thickness TE of the laminated portion 7. As a matter of course, the first width W1 may be not less than the epi thickness TE.

The first width W1 may be not less than 0.1 μm and not more than 10 μm. The first width W1 may have a value belonging to any one range among not less than 0.1 μm and not more than 0.25 μm, exceeding 0.25 μm and not more than 0.5 μm, exceeding 0.5 μm and not more than 0.75 μm, exceeding 0.75 μm and not more than 1 μm, exceeding 1 μm and not more than 1.5 μm, exceeding 1.5 μm and not more than 2 μm, exceeding 2 μm and not more than 2.5 μm, exceeding 2.5 μm and not more than 3 μm, exceeding 3 μm and not more than 3.5 μm, exceeding 3.5 μm and not more than 4 μm, exceeding 4 μm and not more than 4.5 μm, exceeding 4.5 μm and not more than 5 μm, exceeding 5 μm and not more than 5.5 μm, exceeding 5.5 μm and not more than 6 μm, exceeding 6 μm and not more than 6.5 μm, exceeding 6.5 μm and not more than 7 μm, exceeding 7 μm and not more than 7.5 μm, exceeding 7.5 μm and not more than 8 μm, exceeding 8 μm and not more than 8.5 μm, exceeding 8.5 μm and not more than 9 μm, exceeding 9 μm and not more than 9.5 μm, and exceeding 9.5 μm and not more than 10 μm. The first width W1 is preferably not less than 0.5 μm and not more than 1.5 μm.

Each of the plurality of first pillar regions 13 has a first thickness T1. The first thickness T1 may be referred to as a depth of the plurality of first pillar regions 13. The first thickness T1 may be less than the epi thickness TE of the laminated portion 7. The first thickness T1 may be greater than the epi thickness TE. The first thickness T1 may be substantially equal to the epi thickness TE.

The first thickness T1 is preferably not less than 1 μm. The first thickness T1 is preferably not more than 30 μm. The first thickness T1 may have a value belonging to any one range among not less than 1 μm and not more than 1.5 μm, exceeding 1.5 μm and not more than 2 μm, exceeding 2 μm and not more than 2.5 μm, exceeding 2.5 μm and not more than 3 μm, exceeding 3 μm and not more than 3.5 μm, exceeding 3.5 μm and not more than 4 μm, exceeding 4 μm and not more than 4.5 μm, exceeding 4.5 μm and not more than 5 μm, exceeding 5 μm and not more than 10 μm, exceeding 10 μm and not more than 15 μm, exceeding 15 μm and not more than 20 μm, exceeding 20 μm and not more than 25 μm, and exceeding 25 μm and not more than 30 μm.

Preferably, the first width W1 is less than the epi thickness TE of the laminated portion 7, and the first thickness T1 is greater than the first width W1. That is, each of the plurality of first pillar regions 13 preferably has a first aspect ratio T1/W1 extending in a vertically long columnar shape along the thickness direction of the laminated portion 7. The first aspect ratio T1/W1 is a ratio of the first thickness T1 to the first width W1. In this case, the first thickness T1 is particularly preferably greater than the epi thickness TE. For example, the first aspect ratio T1/W1 may exceed 1 and be not more than 100.

The plurality of first pillar regions 13 are formed at intervals of a first pitch P1 in the first direction X. The first pitch P1 is preferably less than the epi thickness TE of the laminated portion 7. As a matter of course, the first pitch P1 may be not less than the epi thickness TE.

The first pitch P1 may be not less than 0.1 μm and not more than 10 μm. The first pitch P1 may have a value belonging to any one range among not less than 0.1 μm and not more than 0.25 μm, exceeding 0.25 μm and not more than 0.5 μm, exceeding 0.5 μm and not more than 0.75 μm, exceeding 0.75 μm and not more than 1 μm, exceeding 1 μm and not more than 1.5 μm, exceeding 1.5 μm and not more than 2 μm, exceeding 2 μm and not more than 2.5 μm, exceeding 2.5 μm and not more than 3 μm, exceeding 3 μm and not more than 3.5 μm, exceeding 3.5 μm and not more than 4 μm, exceeding 4 μm and not more than 4.5 μm, exceeding 4.5 μm and not more than 5 μm, exceeding 5 μm and not more than 5.5 μm, exceeding 5.5 μm and not more than 6 μm, exceeding 6 μm and not more than 6.5 μm, exceeding 6.5 μm and not more than 7 μm, exceeding 7 μm and not more than 7.5 μm, exceeding 7.5 μm and not more than 8 μm, exceeding 8 μm and not more than 8.5 μm, exceeding 8.5 μm and not more than 9 μm, exceeding 9 μm and not more than 9.5 μm, and exceeding 9.5 μm and not more than 10 μm. The first pitch P1 is preferably not less than 0.5 μm and not more than 1.5 μm.

In this embodiment, the drift region 8 of the active region 10 is entirely or partially replaced with the first pillar region 13 and the second pillar region 12. The drift region 8 may be formed (remain) outside a formation region of the first pillar region 13 and the second pillar region 12 in the active region 10. FIG. 5 shows a mode in which the drift region 8 is not formed in the active region 10 and the drift region 8 is formed only in the outer peripheral region 11 for clarification of the basic embodiments of the first pillar region 13 and the second pillar region 12. Although not shown in FIG. 5, the drift region 8 may remain in the active region 10.

Since the first pillar region 13 is an impurity region in which the conductivity type of the drift region 8 is maintained, it may be simply referred to as a drift region. In consideration of the concentration difference between the first pillar region 13 and the drift region 8 (the concentration of the first pillar region 13>the concentration of the drift region 8), the first pillar region 13 may be referred to as a “high concentration drift region,” and the drift region 8 may be referred to as a “low concentration drift region.” Also, considering that the first pillar region 13 is formed in the drift region 8 after the formation of the drift region 8, the drift region 8 may be referred to as a “base drift region,” and the first pillar region 13 may be referred to as a “second drift region.”

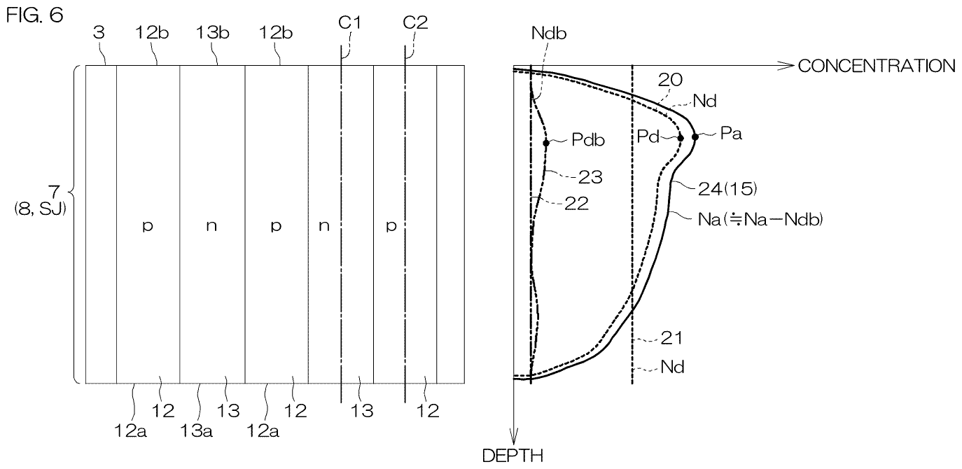

Hereinafter, concentration gradients of the impurity concentration of the drift region 8, the first pillar region 13, and the second pillar region 12, and a charge balance CB of the super junction structure SJ will be specifically described with reference to FIGS. 6 to 8.

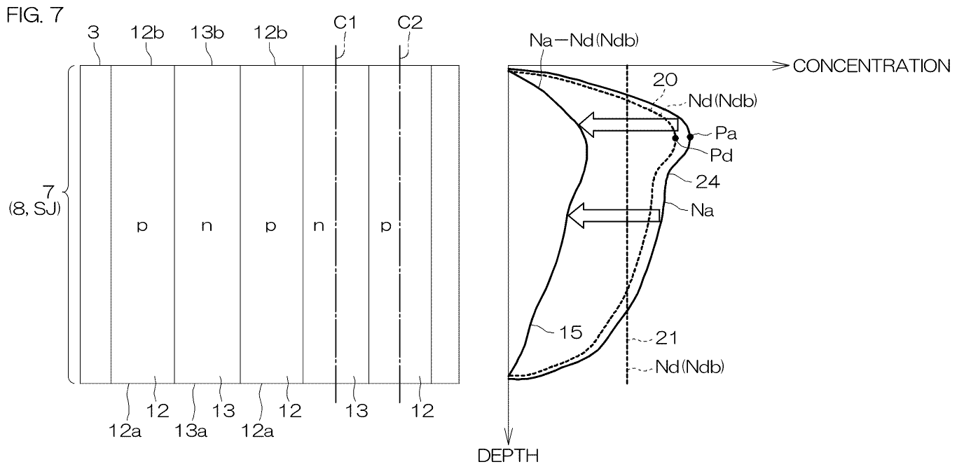

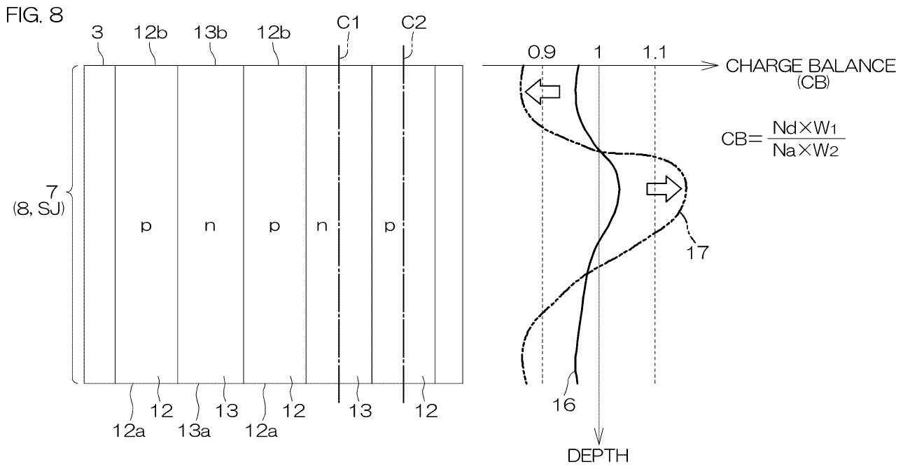

FIG. 6 is a profile showing an example of the concentration gradients of the drift region 8, the first pillar region 13, and the second pillar region 12. FIG. 7 is a profile showing a reference example of the concentration gradients of the drift region 8 (the same concentration as the first pillar region 13) and the second pillar region 12. FIG. 8 is a diagram showing a distribution of the charge balance CB in a depth direction of the super junction structure SJ.

In each of FIGS. 6 and 7, the vertical axis represents the depths of the drift region 8, the first pillar region 13, and the second pillar region 12 with the first principal surface 3, the first upper end portion 13b, and the second upper end portion 12b as references (zero points). In this embodiment, the depths of the first pillar region 13 and the second pillar region 12 are the same as the thicknesses of the first pillar region 13 and the second pillar region 12, respectively. The horizontal axis represents the n-type impurity concentration of the drift region 8, the n-type impurity concentration of the first pillar region 13, and the p-type impurity concentration of the second pillar region 12.

In each of FIGS. 6 and 7, the concentration profiles of the drift region 8 and the second pillar region 12 are concentration profiles at a central position C2 of the second pillar region 12 in a width direction. That is, the n-type impurity concentration of the drift region 8 here indicates a background concentration (Ndb) of the second pillar region 12 replaced from the drift region 8. The concentration profile of the first pillar region 13 is a concentration profile at a central position C1 of the first pillar region 13 in a width direction.

Referring to FIG. 6, first profiles 20 and 21 indicated by broken lines are examples of the profile of the n-type impurity concentration of the first pillar region 13. The profile of the n-type impurity concentration of the first pillar region 13 can have various shapes based on a method of adding n-type impurity ions (ion addition at the time of epitaxial growth, or ion implantation such as a random implantation method or a channeling implantation method), addition conditions (implantation conditions such as dosage, implantation temperature, and implantation energy), a relationship between an incident angle (implantation direction) of the n-type impurity ions and a crystal axis of the laminated portion 7, and the like.

For example, the n-type impurity concentration of the first pillar region 13 may be formed in a substantially mountain-shape having a first peak portion Pd at a certain depth position as indicated by the first profile 20. In this case, the first profile 20 may have a portion (gradual increase portion) where the n-type impurity concentration gradually increases to the first peak portion Pd at a comparatively steep increase rate from the first upper end portion 13b toward the first lower end portion 13a, and a portion (gradual decrease portion) which is formed in a region further to the first lower end portion 13a side than the first peak portion Pd and where the impurity concentration gradually decreases at a comparatively slow decrease rate.

The first peak portion Pd is a portion having a peak value (maximum value) of the n-type impurity concentration. The first peak portion Pd is also a main concentration transition portion of convex shape that includes a series of concentration changes (an inflection point) with which the n-type impurity concentration changes from increasing (an increasing trend) to decreasing (a decreasing trend).

Also, the n-type impurity concentration of the first pillar region 13 may exhibit the first profile 21 having no specific peak value and having a substantially flat shape in a depth direction. In this case, the first pillar region 13 may have an n-type impurity concentration that is fixed in the depth direction. Therefore, in the first profile 21, the n-type impurity concentration at an arbitrary depth position may be the maximum value (peak value) of the n-type impurity concentration of the first pillar region 13.

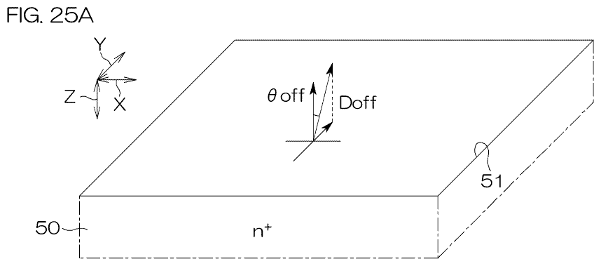

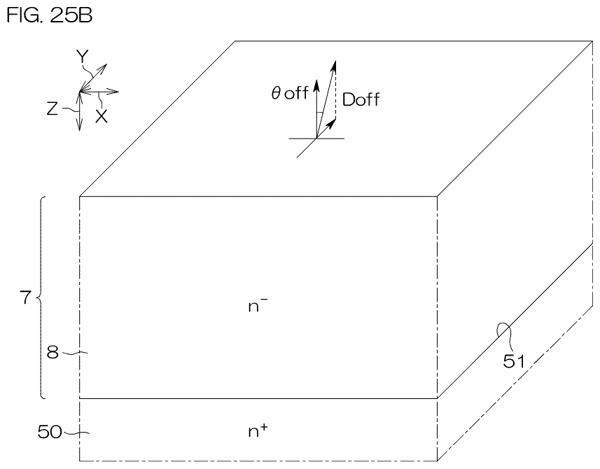

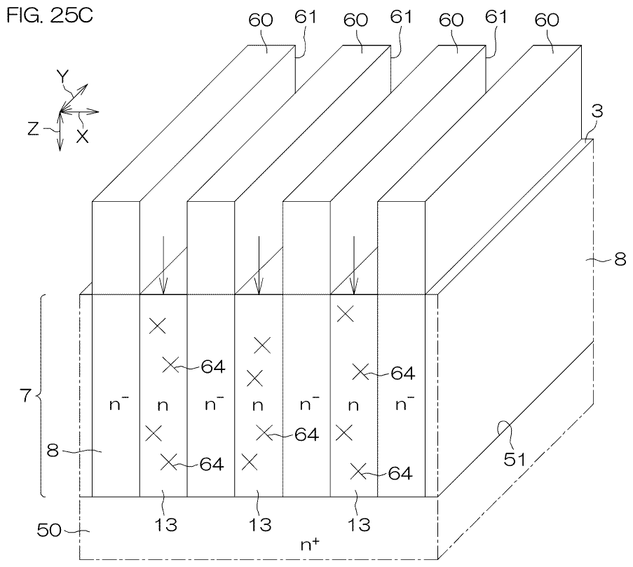

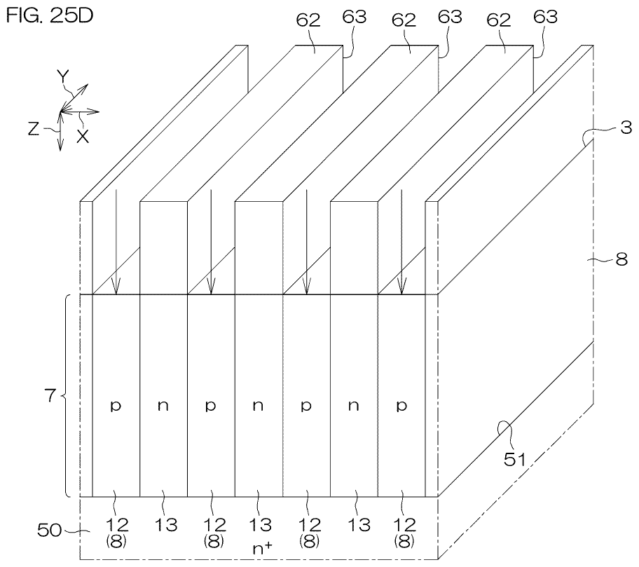

In this embodiment, since the first pillar region 13 is formed by ion implantation into the laminated portion 7 (see FIG. 25C), a concentration gradient drawn by the substantially mountain-shaped first profile 20 is shown. The profile of the n-type impurity concentration of the first pillar region 13 may have a shape other than the shapes of the first profiles 20 and 21.

The first pillar region 13 may have an n-type impurity concentration higher than a peak value (maximum value) of the n-type impurity concentration of the drift region 8 as a maximum value (peak value). More specifically, the first pillar region 13 may have an n-type impurity concentration of not less than 1×10¹⁵ cm⁻³ and not more than 1×10¹⁸ cm⁻³ as a peak value. When the n-type impurity concentration of the first pillar region 13 indicates the substantially mountain-shaped first profile 20, the value of the first peak portion Pd may be a maximum value (peak value) of not less than 1×10¹⁵ cm⁻³ and not more than 1×10¹⁸ cm⁻³. On the other hand, when the n-type impurity concentration of the first pillar region 13 indicates the flat first profile 21, the value of the n-type impurity concentration at an arbitrary depth position may be a maximum value (peak value) of not less than 1×10¹⁵ cm⁻³ and not more than 1×10¹⁸ cm⁻³.

Referring to FIG. 6, drift profiles 22 and 23 indicated by alternate long and two short dashed lines are examples of the profile of the n-type impurity concentration of the drift region 8. The profile of the n-type impurity concentration of the drift region 8 can have various shapes based on a method of adding n-type impurity ions (ion addition at the time of epitaxial growth, or ion implantation such as a random implantation method or a channeling implantation method), addition conditions (implantation conditions such as dosage, implantation temperature, and implantation energy), a relationship between an incident angle (implantation direction) of the n-type impurity ions and the crystal axis of the laminated portion 7, and the like.

For example, the n-type impurity concentration of the drift region 8 may exhibit the drift profile 22 having no specific peak value and having a substantially flat shape in a depth direction. In this case, the drift region 8 may have an n-type impurity concentration that is fixed in the depth direction. Therefore, in the drift profile 22, the n-type impurity concentration at an arbitrary depth position may be the maximum value of the n-type impurity concentration of the drift region 8. In this embodiment, the drift region 8 is a region that maintains the impurity concentration of the laminated portion 7 formed by epitaxial growth (see FIG. 25B). The drift region 8 thus exhibits a concentration gradient drawn by the flat drift profile 22.

On the other hand, the drift region 8 may be formed by ion implantation after epitaxial growth of the laminated portion 7. In this case, the n-type impurity concentration of the drift region 8 may be formed in the substantially mountain-shape having a drift peak portion Pdb at a certain depth position as indicated by the drift profile 23. In this case, the drift profile 23 may have a portion (gradual increase portion) where the n-type impurity concentration gradually increases to the drift peak portion Pdb at a comparatively steep increase rate from the second upper end portion 12b toward the second lower end portion 12a, and a portion (gradual decrease portion) which is formed in a region further to the second lower end portion 12a side than the drift peak portion Pdb and where the impurity concentration gradually decreases at a comparatively slow decrease rate. The profile of the n-type impurity concentration of the drift region 8 may have a shape other than the shapes of the drift profiles 22 and 23.

The drift peak portion Pdb is a portion having a peak value (maximum value) of the n-type impurity concentration. The drift peak portion Pdb is also a main concentration transition portion of convex shape that includes a series of concentration changes (an inflection point) with which the n-type impurity concentration changes from increasing (an increasing trend) to decreasing (a decreasing trend).

The drift region 8 may have an n-type impurity concentration lower than the maximum value (peak value) of the n-type impurity concentration of the first pillar region 13 as a maximum value (peak value). More specifically, the drift region 8 may have an n-type impurity concentration of not less than 1×10¹⁵ cm⁻³ and not more than 1×10¹⁷ cm⁻³ as a peak value. When the n-type impurity concentration of the drift region 8 indicates the flat drift profile 22, the value of the n-type impurity concentration at an arbitrary depth position may be a maximum value (peak value) of not less than 1×10¹⁵ cm⁻³ and not more than 1×10¹⁷ cm⁻³. On the other hand, when the n-type impurity concentration of the drift region 8 indicates the substantially mountain-shaped drift profile 23, the value of the drift peak portion Pdb may be a maximum value (peak value) of not less than 1×10¹⁵ cm⁻³ and not more than 1×10¹⁷ cm⁻³.

The maximum value (peak value) of the drift profiles 22 and 23 is not more than ½ of the maximum value (peak value) of the first profile 21 of the first pillar region 13. More preferably, the maximum value (peak value) of the drift profiles 22 and 23 is smaller than the maximum value (peak value) of the first profile 21 of the first pillar region 13 by at least one order of magnitude. In other words, the maximum value (peak value) of the drift profiles 22 and 23 is not more than 1/10 of the maximum value (peak value) of the first profile 21 of the first pillar region 13.

Referring to FIG. 6, a second profile 24 indicated by a solid line is an example of the profile of the p-type impurity concentration of the second pillar region 12. The profile of the p-type impurity concentration of the second pillar region 12 can have various shapes based on a method of adding p-type impurity ions (ion implantation such as a random implantation method or a channeling implantation method), addition conditions (implantation conditions such as dosage, implantation temperature, and implantation energy), a relationship between an incident angle (implantation direction) of the p-type impurity ions and the crystal axis of the laminated portion 7, and the like.

For example, the p-type impurity concentration of the second pillar region 12 may be formed in a substantially mountain-shape having a second peak portion Pa at a certain depth position as indicated by the second profile 24. In this case, the second profile 24 may have a portion (gradual increase portion) where the p-type impurity concentration gradually increases to the second peak portion Pa at a comparatively steep increase rate from the second upper end portion 12b toward the second lower end portion 12a, and a portion (gradual decrease portion) which is formed in a region further to the second lower end portion 12a side than the second peak portion Pa and where the impurity concentration gradually decreases at a comparatively slow decrease rate. In this embodiment, the second pillar region 12 is a region formed by ion implantation into the laminated portion 7 after formation of the laminated portion 7 having a conductivity type (n-type in this embodiment) opposite to that of the second pillar region 12 (see FIG. 25D). Therefore, the second pillar region 12 shows a concentration gradient drawn by the substantially mountain-shaped second profile 24.

The second peak portion Pa is a portion having a peak value (maximum value) of the p-type impurity concentration. The second peak portion Pa is also a main concentration transition portion of convex shape that includes a series of concentration changes (an inflection point) with which the p-type impurity concentration changes from increasing (an increasing trend) to decreasing (a decreasing trend).

Ideally, the maximum value (peak value) of the p-type impurity concentration of the second pillar region 12 is a value calculated based on the dosage of the p-type impurity ions implanted into the laminated portion 7. More specifically, the second pillar region 12 may have a p-type impurity concentration of not less than 1×10¹⁵ cm⁻³ and not more than 1×10¹⁸ cm⁻³ as a peak value. When the p-type impurity concentration of the second pillar region 12 indicates the substantially mountain-shaped second profile 24, the value of the second peak portion Pa may be a maximum value (peak value) of not less than 1×10¹⁵ cm⁻³ and not more than 1×10¹⁸ cm⁻³.

On the other hand, the second pillar region 12 is formed inside the drift region 8, which is a base region having a conductivity type opposite to that of the second pillar region 12, and replaces the drift region 8. Therefore, an effective p-type impurity concentration (effective acceptor concentration) of the second pillar region 12 is a value (Na−Ndb) obtained by subtracting the concentration of the drift region 8 as a background concentration Ndb of the second pillar region 12 from an ideal p-type impurity concentration (ideal value Na) of the second pillar region 12.

Referring to FIG. 6, the background concentration Ndb of the second pillar region 12 is a concentration of the drift region 8 lower than a concentration Nd of the first pillar region 13. Therefore, the effective p-type impurity concentration (Na−Ndb) of the second pillar region 12 can be brought close to the ideal p-type impurity concentration Na of the second pillar region 12. That is, since (Na−Ndb)≈Na is satisfied, a profile (an effective profile 15) of the effective p-type impurity concentration (Na−Ndb) of the second pillar region 12 can be expressed by the second profile 24 indicating the ideal p-type impurity concentration Na of the second pillar region 12. As a result, the effective profile 15 (effective p-type profile) of the second pillar region 12 and the first profile 20 (n-type profile) of the first pillar region 13 can be equal to or close to each other.

In the super junction structure SJ, the approximation of the effective acceptor concentration (Na−Ndb) of the second pillar region 12 and the donor concentration Nd of the first pillar region 13 contributes to the stabilization of the charge balance of the super junction structure SJ. When the donor concentration of the first pillar region 13 is Nd, the width of the first pillar region 13 is W1, the acceptor concentration of the second pillar region 12 is Na, and the width of the second pillar region 12 is W2, the charge balance CB between the first pillar region 13 and the second pillar region 12 is represented by the following formula (1).

CB=(Nd×W1)/(Na×W2) . . . (1)

According to this embodiment, the maximum value of the background concentration Ndb of the second pillar region 12 is the concentration of the drift region 8 and is small. Even if the background concentration Ndb varies in a depth direction of the laminated portion 7, an influence of the variation on the effective acceptor concentration (Na−Ndb) of the second pillar region 12 can thereby be reduced. Therefore, the effective acceptor concentration (Na−Ndb) of the second pillar region 12 can be stabilized to be substantially equal to the acceptor concentration Na of the second pillar region 12. As a result, the influence on the charge balance CB between the first pillar region 13 and the second pillar region 12 can be reduced, and thus, it is possible to suppress fluctuation in a withstand voltage caused by collapse of the charge balance CB (charge imbalance). Therefore, the withstand voltage performance of the semiconductor device 1A can be further improved by the super junction structure SJ.

In addition, since the effective acceptor concentration (Na−Ndb) of the second pillar region 12 and the donor concentration Nd of the first pillar region 13 are approximated, the charge balance CB can be brought close to 1. As a result, the charge balance CB can be stabilized. For example, the effective acceptor concentration (Na−Ndb) of the second pillar region 12 can be set to not less than 90% and not more than 110% of the donor concentration Nd of the first pillar region 13.

Further, the background concentration Ndb of the second pillar region 12 is the concentration of the drift region 8. For example, when the drift region 8 is formed by epitaxial growth, a raw material gas of the drift region 8 is supplied while n-type impurity ions are added in the crystal growth process. Since the impurity distribution in the epitaxial layer (the drift region 8) can be easily controlled, for example, the drift impurity concentration (the background concentration Ndb) can be made fixed or substantially fixed in a depth direction of the epitaxial layer.

Since the background concentration Ndb can also thereby be made fixed or substantially fixed, it is possible to effectively reduce the variation in a depth direction of the effective acceptor concentration (Na−Ndb) in the second pillar region 12. As a result, it is possible to further suppress the fluctuation in the withstand voltage caused by the charge imbalance of the super junction structure SJ. For example, as shown in FIG. 8, in a section from an apex portion (the first upper end portion 13b, the second upper end portion 12b) to a bottom portion (the first lower end portion 13a, the second lower end portion 12a) in the depth direction of the super junction structure SJ, as indicated by a solid line 16, the charge balance CB can be kept within a range of not less than 0.9 and not more than 1.1.

Since the charge balance CB is stabilized, the width W1 of the first pillar region 13 and the width W2 of the second pillar region 12 can be made equal to each other. As a result, it is not necessary to narrow or widen only the width of one of the first pillar region 13 and the second pillar region 12. Therefore, since the super junction structure SJ can be formed at high density, the withstand voltage can be further improved.

On the other hand, as shown in FIG. 7, when the background concentration Ndb of the second pillar region 12 is the same as or substantially the same as the concentration Nd of the first pillar region 13, the n-type impurity that compensates the p-type impurity of the second pillar region 12 is greater than that in the case of FIG. 6. For example, there is a case where the profile of the background concentration Ndb is represented by the first profile 20 or the first profile 21 in FIG. 6. In this case, the p-type impurity of the second pillar region 12 is largely compensated by the background n-type impurity. As a result, as shown in FIG. 7, the effective profile 15 shifts to the low concentration side, and the effective acceptor concentration (Na−Ndb) of the second pillar region 12 and the donor concentration Nd (the first profile 20) of the first pillar region 13 are separated from each other. Therefore, it becomes difficult to secure the charge balance CB.

In addition, in a case where the background concentration Ndb of the second pillar region 12 is provided by an impurity region formed by ion implantation into the laminated portion 7, the background concentration Ndb may vary in a depth direction depending on the environment of ion implantation or the like. For example, there is a case where the drift region 8 is replaced with the donor concentration Nd of the first pillar region 13 by implanting n-type impurity ions into the entire laminated portion 7 after the epitaxial growth of the laminated portion 7. In the case of ion implantation, it is difficult to form an impurity concentration at a fixed concentration in the depth direction of the laminated portion 7. Therefore, even if the second pillar region 12 is formed by implantation of p-type impurity ions exceeding the concentration of the first pillar region 13, it is difficult to avoid the influence of the variation in the donor concentration Nd. As a result, charge imbalance occurs, and the charge balance CB may vary greatly in the depth direction, for example, as indicated by an alternate long and two short dashed line 17 in FIG. 8. In the semiconductor device 1A of this embodiment, it is possible to suppress the fluctuation in the withstand voltage caused by such charge imbalance.

Hereinafter, first to eleventh configuration examples of the second pillar region 12 will be described with reference to FIGS. 8 to 19. The plurality of second pillar regions 12 may have at least one of a plurality of features shown in the first to eleventh configuration examples. The plurality of second pillar regions 12 may have a feature in which a plurality of (not less than two) features shown in the first to eleventh configuration examples are combined.

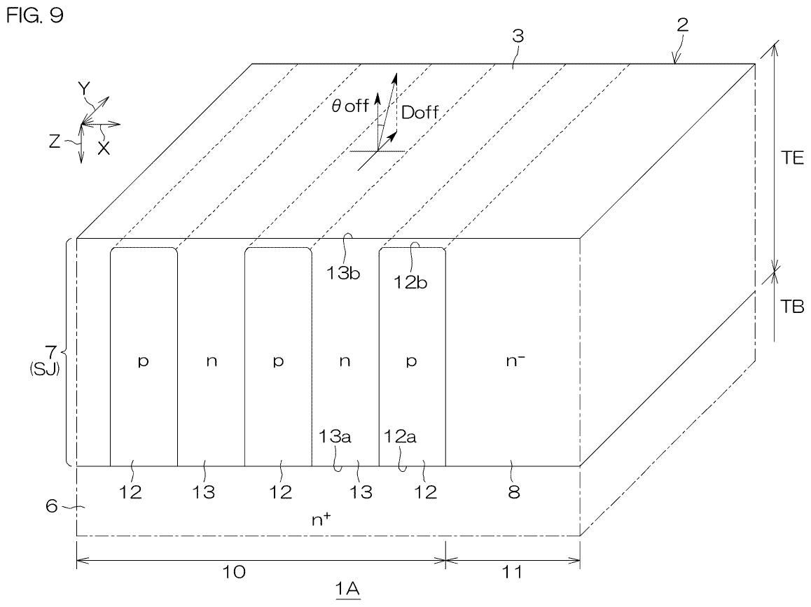

FIG. 9 is a sectional perspective view showing the second pillar region 12 according to the first configuration example. Referring to FIG. 9, the second pillar region 12 has a thickness less than the epi thickness TE of the laminated portion 7, and is formed in the laminated portion 7 (the drift region 8) at an interval from the upper end of the laminated portion 7. Specifically, the second upper end portion 12b of the second pillar region 12 is formed at an interval to the lower end side from the upper end (the first principal surface 3) of the laminated portion 7, and faces the first principal surface 3 with a portion (the upper end portion) of the laminated portion 7 interposed therebetween.

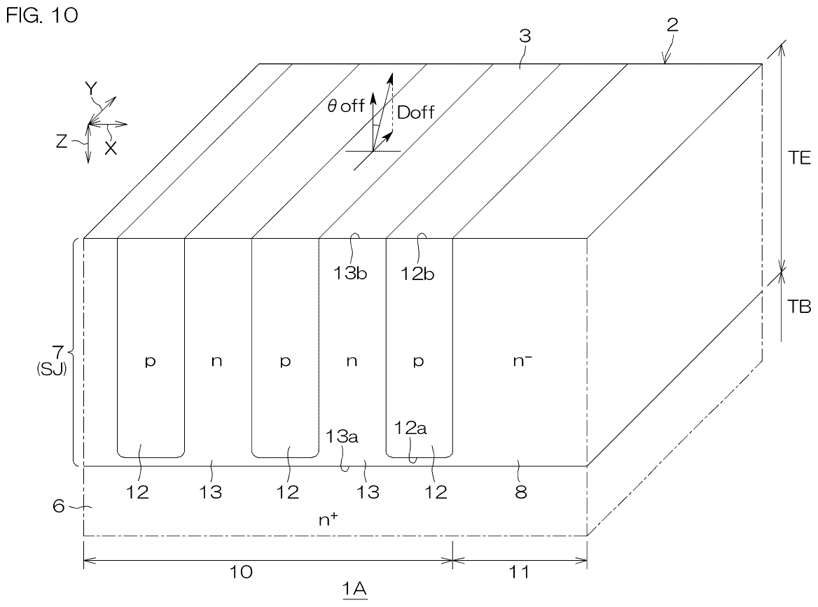

FIG. 10 is a sectional perspective view showing the second pillar region 12 according to the second configuration example. Referring to FIG. 10, the second pillar region 12 has a thickness less than the epi thickness TE of the laminated portion 7, and is formed in the laminated portion 7 (the drift region 8) at an interval from the lower end of the laminated portion 7. Specifically, the second lower end portion 12a of the second pillar region 12 is formed at an interval to the upper end side from the lower end (the base layer 6) of the laminated portion 7, and faces the base layer 6 with a portion (the lower end portion) of the laminated portion 7 interposed therebetween.

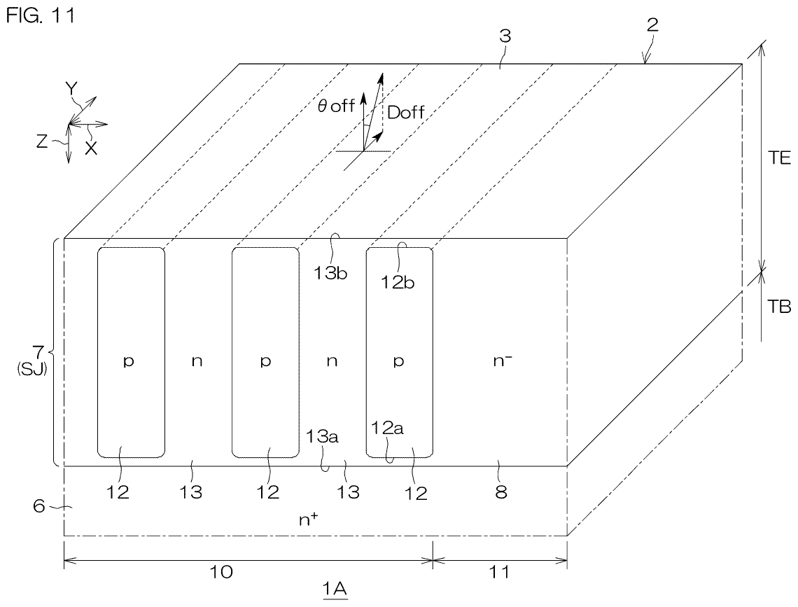

FIG. 11 is a sectional perspective view showing the second pillar region 12 according to the third configuration example. Referring to FIG. 11, the second pillar region 12 has a thickness less than the epi thickness TE of the laminated portion 7, and is formed in the laminated portion 7 (the drift region 8) at an interval from both the lower end and the upper end of the laminated portion 7. Specifically, the second upper end portion 12b of the second pillar region 12 is formed at an interval to the lower end side from the upper end (the first principal surface 3) of the laminated portion 7, and faces the first principal surface 3 with a portion (the upper end portion) of the laminated portion 7 interposed therebetween. On the other hand, the second lower end portion 12a of the second pillar region 12 is formed at an interval to the upper end side from the lower end (the base layer 6) of the laminated portion 7, and faces the base layer 6 with a portion (the lower end portion) of the laminated portion 7 interposed therebetween.

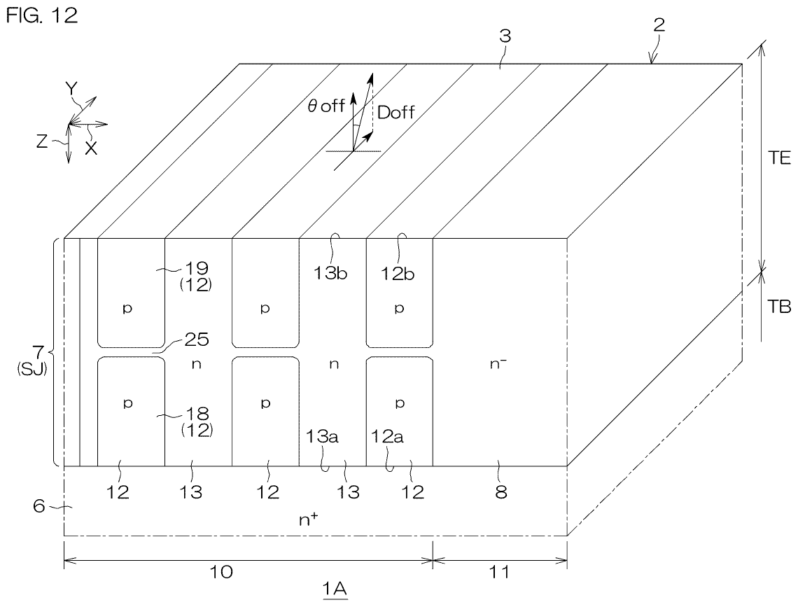

FIG. 12 is a sectional perspective view showing the second pillar region 12 according to the fourth configuration example. Referring to FIG. 12, each of the plurality of second pillar regions 12 has a laminated structure including a first region 18 and a second region 19 in the thickness direction of the laminated portion 7. In this embodiment, the first region 18 and the second region 19 are disposed at an interval from each other in the thickness direction of the laminated portion 7. The first region 18 and the second region 19 may each independently have a concentration gradient of the p-type impurity concentration represented by the second profile 24 (the effective profile 15) shown in FIG. 6.

A portion of the laminated portion 7 (the drift region 8) is interposed between the first region 18 and the second region 19. The portion of the drift region 8 provides an intermediate region 25 of the n-type that physically separates the first region 18 and the second region 19. The intermediate region 25 may be positioned at a center in the thickness direction of the laminated portion 7, or may be positioned on the upper end side or the lower end side with respect to the central position.

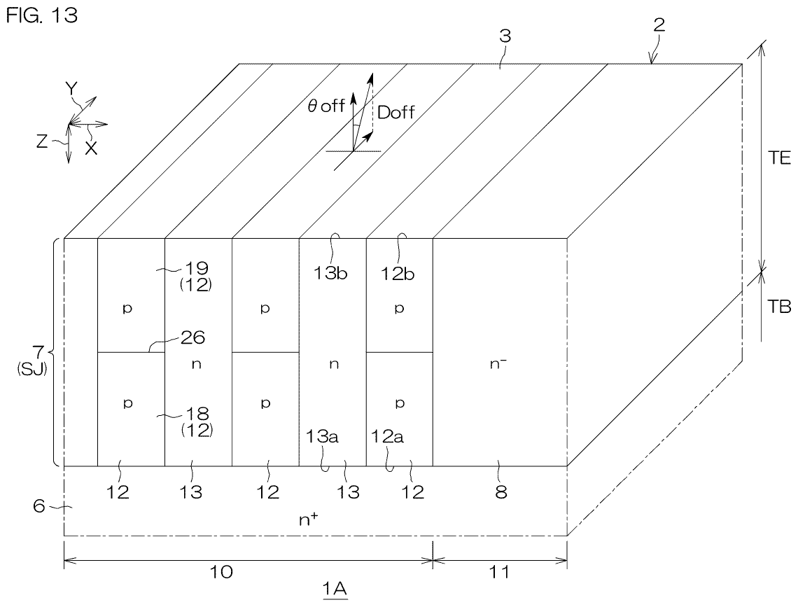

FIG. 13 is a sectional perspective view showing the second pillar region 12 according to the fifth configuration example. Referring to FIG. 13, each of the plurality of second pillar regions 12 has a laminated structure including the first region 18 and the second region 19 in the thickness direction of the laminated portion 7. In this embodiment, the first region 18 and the second region 19 are connected to each other in the thickness direction of the laminated portion 7. The first region 18 and the second region 19 may each independently have a concentration gradient of the p-type impurity concentration represented by the second profile 24 (the effective profile 15) shown in FIG. 6. A boundary portion 26 between the first region 18 and the second region 19 may be positioned at the center in the thickness direction of the laminated portion 7, or may be positioned on the upper end side or the lower end side with respect to the central position.

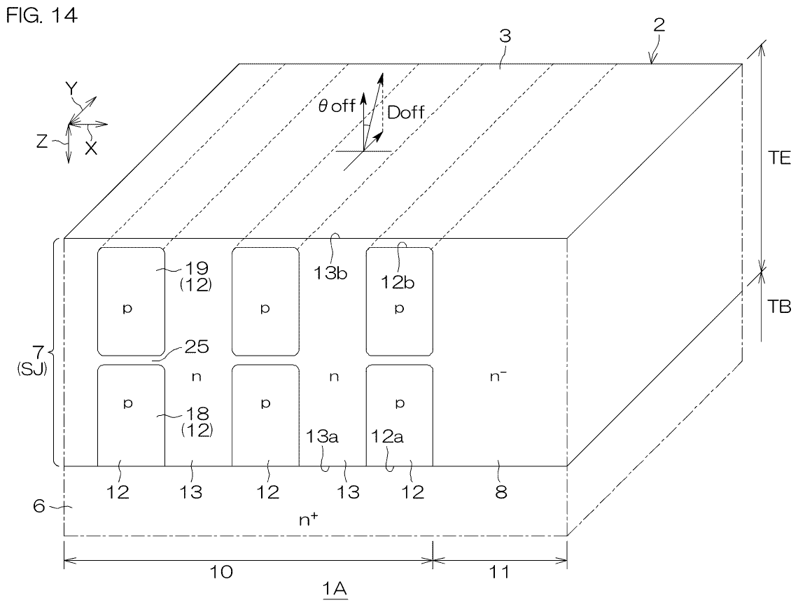

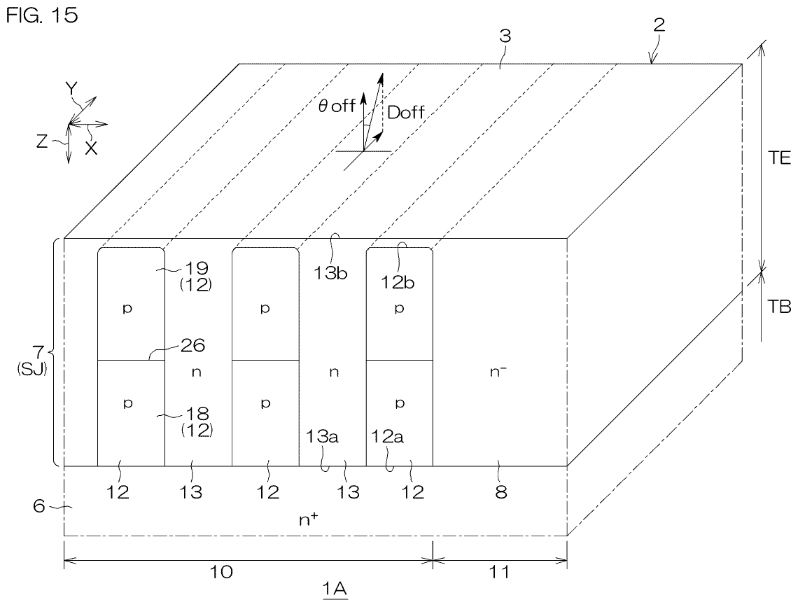

FIG. 14 is a sectional perspective view showing the second pillar region 12 according to the sixth configuration example. FIG. 15 is a sectional perspective view showing the second pillar region 12 according to the seventh configuration example. Referring to FIGS. 14 and 15, the second pillar region 12 having the second upper end portion 12b at a position at an interval from the upper end of the laminated portion 7 may have a laminated structure including the first region 18 and the second region 19.

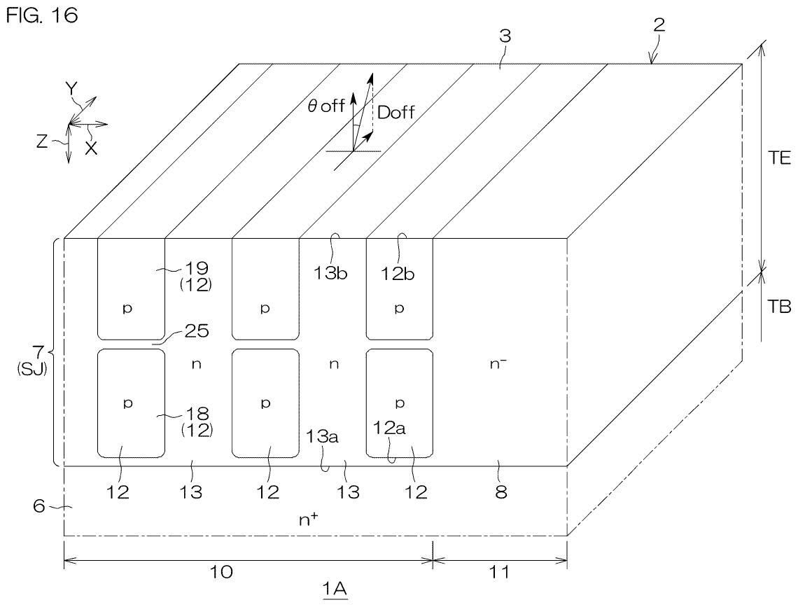

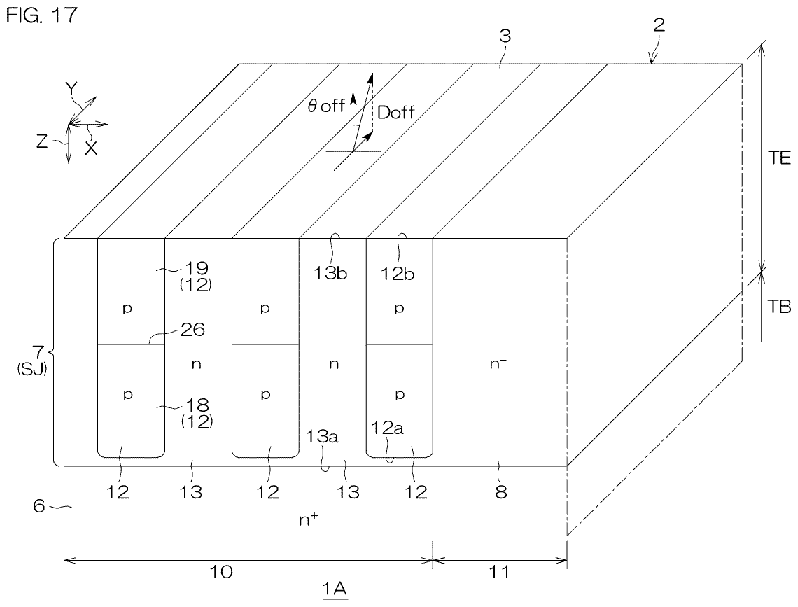

FIG. 16 is a sectional perspective view showing the second pillar region 12 according to the eighth configuration example. FIG. 17 is a sectional perspective view showing the second pillar region 12 according to the ninth configuration example. Referring to FIGS. 16 and 17, the second pillar region 12 having the second lower end portion 12a at a position at an interval from the lower end of the laminated portion 7 may have a laminated structure including the first region 18 and the second region 19.

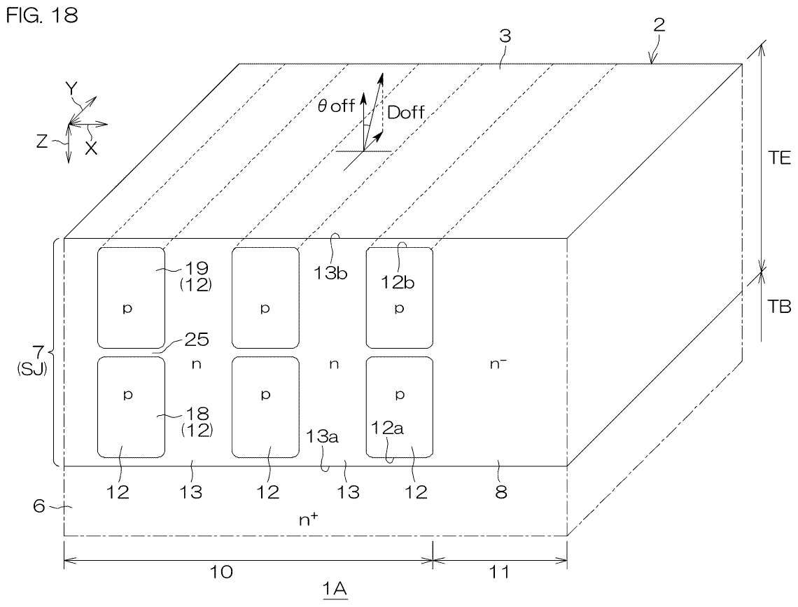

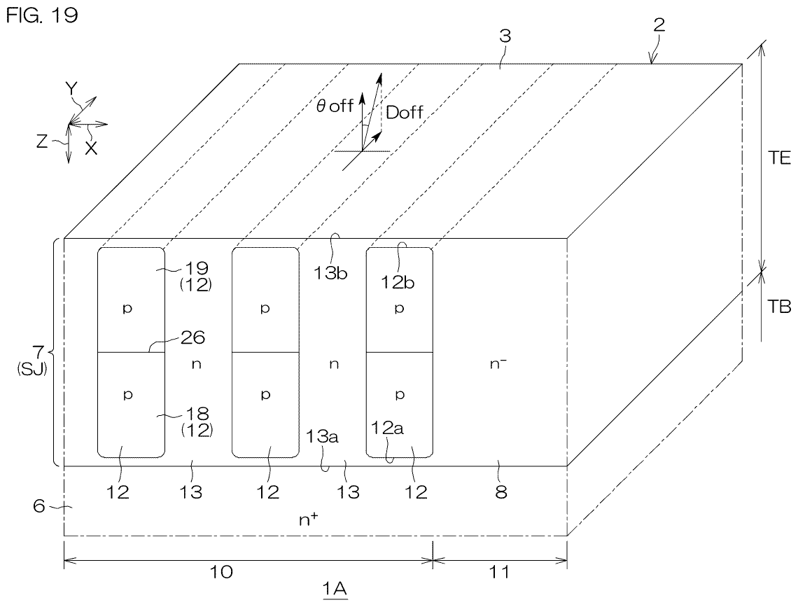

FIG. 18 is a sectional perspective view showing the second pillar region 12 according to the tenth configuration example. FIG. 19 is a sectional perspective view showing the second pillar region 12 according to the eleventh configuration example. Referring to FIGS. 18 and 19, the second pillar region 12 respectively having the second upper end portion 12b and the second lower end portion 12a at positions at an interval from the upper end and the lower end of the laminated portion 7 may have a laminated structure including the first region 18 and the second region 19.

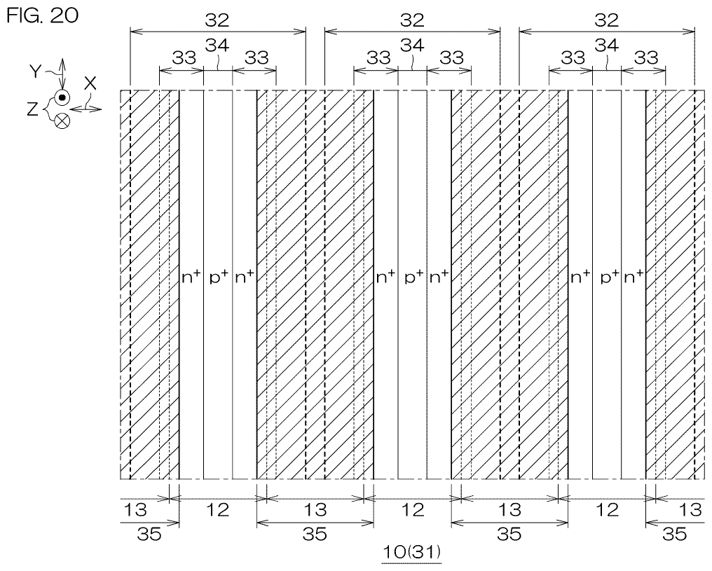

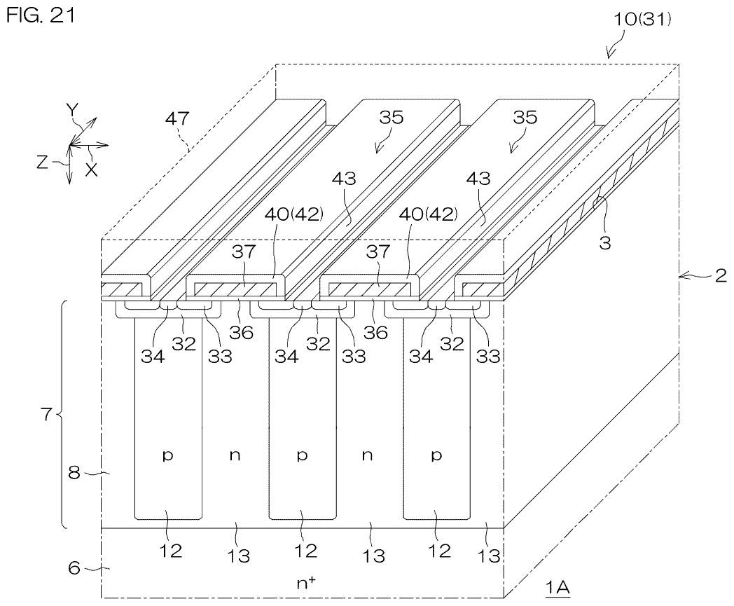

Hereinafter, a configuration example of a device structure formed in the active region 10 will be described. FIG. 20 is a plan view showing a principal portion of the active region 10. FIG. 21 is a sectional perspective view showing a gate structure 35 according to the first configuration example. In FIG. 21, the second pillar region 12 according to the third configuration example is shown. As a matter of course, in FIG. 21, an arrangement to which any one or more of the second pillar regions 12 according to the basic embodiment and the first to eleventh configuration examples are applied may be applied.

Referring to FIGS. 20 and 21, in this embodiment, the semiconductor device 1A includes an MIS structure 31 (metal insulator semiconductor structure) as an example of a device structure formed in the active region 10. The MIS structure 31 may be referred to as a “field effect transistor structure.”

The semiconductor device 1A includes a plurality of the body regions 32 of the p-type formed in the active region 10. In this embodiment, the plurality of body regions 32 are aligned at intervals in the first direction X and are each formed in a band shape extending in the second direction Y. That is, the plurality of body regions 32 are aligned at intervals in the m-axis direction of the SiC monocrystal, and extend in the a-axis direction of the SiC monocrystal. In other words, an extension direction of the plurality of body regions 32 coincides with the off direction Doff of the SiC monocrystal. Also, the extension direction of the plurality of body regions 32 coincides with the extension direction of the plurality of second pillar regions 12.

The plurality of body regions 32 are formed in a surface layer portion of the first principal surface 3 such as to overlap the second pillar regions 12 corresponding in the lamination direction. Specifically, the plurality of body regions 32 overlap the plurality of second pillar regions 12 in one-to-one correspondence in the lamination direction.

When the plurality of second pillar regions 12 are formed at intervals from the first principal surface 3, the plurality of body regions 32 are formed in regions between the first principal surface 3 and the second upper end portions 12b (see FIG. 11) of the plurality of second pillar regions 12, respectively. Preferably, the plurality of body regions 32 are formed on the first principal surface 3 side with respect to the intermediate portion in the thickness range of the laminated portion 7, and are exposed from the first principal surface 3. The plurality of body regions 32 are preferably connected to the corresponding second pillar regions 12 (the second upper end portions 12b).

Each of the plurality of body regions 32 is formed to be wider than the second pillar region 12 immediately below, and is formed at an interval from the plurality of adjacent second pillar regions 12 toward the second pillar region 12 immediately below. The plurality of body regions 32 expose a portion of the first pillar region 13 from a region of the first principal surface 3 between the plurality of adjacent second pillar regions 12.

The plurality of body regions 32 may have, for example, a p-type impurity concentration of not less than 1×10¹⁵ cm⁻³ and not more than 1×10¹⁸ cm⁻³ as a peak value.

The p-type impurity concentration of the plurality of body regions 32 is preferably adjusted by at least one type of trivalent element. The trivalent element of the body region 32 may be the same type as a trivalent element of the second pillar region 12 or the like or may be a type different from the trivalent element of the second pillar region 12 or the like. The trivalent element of the body region 32 may be at least one type among boron, aluminum, gallium, and indium.

The semiconductor device 1A includes one or a plurality of the source regions 33 of the n-type respectively formed in surface layer portions of the plurality of body regions 32 in the active region 10. In this embodiment, the plurality of (two in this embodiment) source regions 33 are formed at an interval from each other in the surface layer portion of each of the body regions 32. The plurality of source regions 33 have an n-type impurity concentration higher than the n-type impurity concentration of the first pillar region 13 and the drift region 8 of the laminated portion 7. The plurality of source regions 33 may have an n-type impurity concentration of not less than 1×10¹⁸ cm⁻³ and not more than 1×10²¹ cm⁻³ as a peak value.

The plurality of source regions 33 may each extend in a band shape along the extension direction of the corresponding body region 32. As a matter of course, the plurality of source regions 33 may be formed at intervals along the extension direction of the corresponding body region 32. The plurality of source regions 33 are formed at intervals to the first principal surface 3 side from a bottom portion of the corresponding body region 32, and are formed at intervals inward from the peripheral edges of the corresponding body region 32. The plurality of source regions 33 demarcate channels (current paths) along the first principal surface 3 together with the plurality of first pillar regions 13 in peripheral edge portions of the body regions 32.

The semiconductor device 1A includes one or a plurality of the contact regions 34 of the p-type respectively formed in the surface layer portions of the plurality of body regions 32 in the active region 10. The contact regions 34 may be referred to as “back gate regions.” In this embodiment, the single contact region 34 is formed in a region between the plurality of source regions 33 adjacent to each other in the surface layer portion of each of the body regions 32.

The plurality of contact regions 34 have a p-type impurity concentration (peak value) higher than the p-type impurity concentration (peak value) of the plurality of body regions 32. The p-type impurity concentration (peak value) of the plurality of contact regions 34 is higher than the p-type impurity concentration (peak value) of the plurality of second pillar regions 12. The plurality of contact regions 34 may have a p-type impurity concentration of not less than 1×10¹⁸ cm⁻³ and not more than 1×10²¹ cm⁻³ as a peak value.

The plurality of contact regions 34 may each extend in a band shape along the extension direction of the corresponding body region 32. As a matter of course, the plurality of contact regions 34 may be formed at intervals along the extension direction of the corresponding body region 32. The plurality of contact regions 34 are formed at intervals to the first principal surface 3 side from the bottom portion of the corresponding body region 32, and are formed at intervals inward from the peripheral edge portions of the corresponding body region 32.

The semiconductor device 1A includes a plurality of the gate structures 35 of a planar electrode type disposed on the first principal surface 3 in the active region 10. The gate structures 35 may be referred to as “planar gate structures.” The plurality of gate structures 35 are aligned at an interval from each other on the first principal surface 3 such as to overlap at least one of the body regions 32 (channels) in the lamination direction. A gate potential is applied as a control potential to the plurality of gate structures 35. The plurality of gate structures 35 control inversion and non-inversion of channels (current paths) inside the body region 32 in response to the gate potential.

In this embodiment, the plurality of gate structures 35 are aligned at intervals in the first direction X and are each formed in a band shape extending in the second direction Y. That is, the plurality of gate structures 35 are aligned at intervals in the m-axis direction of the SiC monocrystal and extend in the a-axis direction of the SiC monocrystal. In other words, an extension direction of the plurality of gate structures 35 coincides with the off direction Doff of the SiC monocrystal. Also, the extension direction of the plurality of gate structures 35 coincides with the extension direction of the plurality of second pillar regions 12.

The plurality of gate structures 35 are disposed to be shifted from the plurality of second pillar regions 12 toward the plurality of first pillar regions 13, and overlap the plurality of first pillar regions 13 in one-to-one correspondence in the lamination direction. In this embodiment, the plurality of gate structures 35 are disposed such as to extend across the two adjacent body regions 32, respectively, and cover the plurality of source regions 33 positioned in the one and the other body regions 32, respectively.

Each of the plurality of gate structures 35 has a laminated structure including a gate insulating film 36 disposed on the first principal surface 3 and a gate electrode 37 disposed on the gate insulating film 36. The gate insulating film 36 may include a silicon oxide film. The gate electrode 37 may contain a conductive polysilicon.

One or both of the gate insulating film 36 and the gate electrode 37 may be disposed such as to partially overlap the second pillar region 12 in the lamination direction. As a matter of course, one or both of the gate insulating film 36 and the gate electrode 37 may be disposed such as not to partially overlap the second pillar region 12 in the lamination direction.

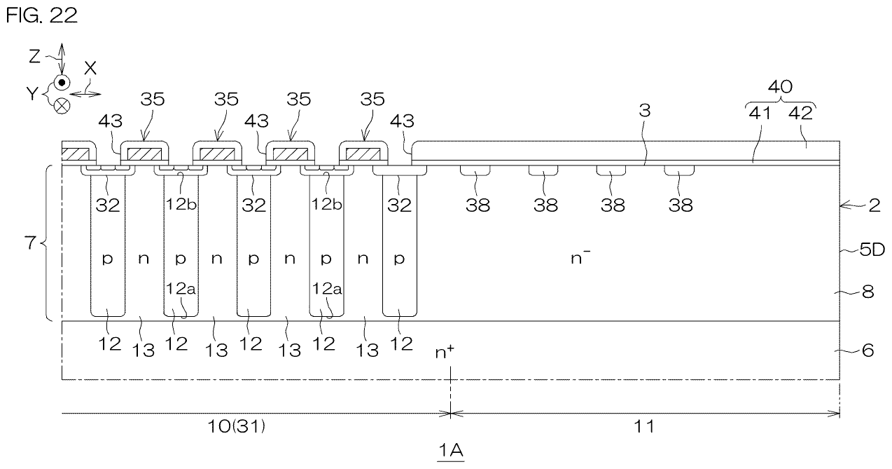

Hereinafter, an arrangement on the outer peripheral region 11 side will be described. FIG. 22 is a sectional view showing a principal portion of the outer peripheral region 11. The semiconductor device 1A includes at least one (preferably, not less than 2 and not more than 20) of field regions 38 of the p-type formed in the surface layer portion of the first principal surface 3 in the outer peripheral region 11.

The number of the plurality of the field regions 38 is typically not less than 4 and not more than 8. The plurality of field regions 38 are formed in an electrically floating state and relax an electric field inside the chip 2 at peripheral edge portions of the first principal surface 3. The number, width, depth, p-type impurity concentration, etc., of the field regions 38 are arbitrary and can take on any of various values in accordance with the electric field to be relaxed.

The plurality of field regions 38 are formed at intervals in a region between the peripheral edges of the chip 2 and the active region 10. The plurality of field regions 38 are formed in band shapes extending along the active region 10 in plan view. The plurality of field regions 38 each have portions extending in a band shape in the first direction X and portions extending in a band shape in the second direction Y. In this embodiment, the plurality of field regions 38 are formed in annular shapes (specifically, quadrilateral annular shapes) surrounding the active region 10 (that is, the plurality of second pillar regions 12) in plan view.

The plurality of field regions 38 are formed in the laminated portion 7 at intervals to the first principal surface 3 side from the lower end of the laminated portion 7 (the drift region 8), and form pn junction portions with the drift region 8, respectively. The plurality of field regions 38 preferably have bottom portions positioned on the first principal surface 3 side with respect to the intermediate portion in the thickness range of the laminated portion 7. In this embodiment, the plurality of field regions 38 are formed at intervals to the peripheral edge sides of the chip 2 from the plurality of second pillar regions 12. The plurality of field regions 38 thus do not face the plurality of second pillar regions 12 in the lamination direction.

The bottom portions of the plurality of field regions 38 may be positioned further to the first principal surface 3 side than a depth position of the second upper end portion 12b of the second pillar region 12. As a matter of course, the bottom portions of the plurality of field regions 38 may be positioned further to the second lower end portion 12a side of the second pillar region 12 than the depth position of the second upper end portion 12b of the second pillar region 12. In this case, the bottom portions of the plurality of field regions 38 are preferably positioned on the first principal surface 3 side with respect to an intermediate portion in a thickness range of the second pillar region 12.

The plurality of field regions 38 may have a thickness that is substantially equal to the thickness of the plurality of body regions 32. In this case, the plurality of field regions 38 can be formed simultaneously with the plurality of body regions 32. As a matter of course, the thickness of the plurality of field regions 38 may be greater than the thickness of the plurality of body regions 32. The thickness of the plurality of field regions 38 may be smaller than the thickness of the plurality of body regions 32.

The plurality of field regions 38 may have a p-type impurity concentration of not less than 1×10¹⁵ cm⁻³ and not more than 1×10¹⁸ cm⁻³ as a peak value.

The p-type impurity concentration of the field region 38 may be substantially equal to the p-type impurity concentration of the body region 32. As a matter of course, the p-type impurity concentration of the plurality of field regions 38 may be higher than the p-type impurity concentration of the plurality of body regions 32. The p-type impurity concentration of the plurality of field regions 38 may be lower than the p-type impurity concentration of the plurality of body regions 32.

The p-type impurity concentration of the plurality of field regions 38 is preferably adjusted by at least one type of trivalent element. The trivalent element of the field region 38 may be the same type as a trivalent element of the second pillar region 12 or the like or may be a type different from the trivalent element of the second pillar region 12 or the like. The trivalent element of the field region 38 may be at least one type among boron, aluminum, gallium, and indium.

The plurality of field regions 38 preferably have a width different from the second width W2 of the second pillar region 12. That is, the electric field relaxation effect by the plurality of field regions 38 is preferably adjusted separately from the plurality of second pillar regions 12.

The width of the plurality of field regions 38 is particularly preferably greater than the second width W2 of the second pillar region 12. As a matter of course, the width of the plurality of field regions 38 may be smaller than the second width W2. In addition, the width of the plurality of field regions 38 may be substantially equal to the second width W2.

The plurality of field regions 38 are preferably formed at a pitch different from the second pitch P2 of the second pillar regions 12. The pitch of the plurality of field regions 38 is particularly preferably greater than the second pitch P2. As a matter of course, the pitch of the plurality of field regions 38 may be smaller than the second pitch P2. The pitch of the plurality of field regions 38 may be substantially equal to the second pitch P2.

The semiconductor device 1A includes an interlayer insulating film 40 that covers the first principal surface 3. The interlayer insulating film 40 may be referred to as an “insulating film,” an “interlayer film,” an “intermediate insulating film,” or the like. In this embodiment, the interlayer insulating film 40 has a laminated structure that includes a first insulating film 41 and a second insulating film 42 (see FIG. 22). The first insulating film 41 may include at least one among a silicon oxide film, a silicon nitride film, and a silicon oxynitride film. The first insulating film 41 particularly preferably includes a silicon oxide film that consists of an oxide of the chip 2 (the laminated portion 7).

The first insulating film 41 selectively covers the first principal surface 3 in the active region 10 and the outer peripheral region 11. The first insulating film 41 covers a region outside the gate insulating film 36 in the active region 10 and is connected to the gate insulating film 36. The first insulating film 41 covers the plurality of field regions 38 in the outer peripheral region 11. In this embodiment, the first insulating film 41 is continuous to the peripheral edges (the first to fourth side surfaces 5A to 5D) of the first principal surface 3. As a matter of course, the first insulating film 41 may be formed at intervals inward from the peripheral edges of the first principal surface 3 and expose the laminated portion 7 from the peripheral edge portions of the first principal surface 3.

The second insulating film 42 is laminated on the first insulating film 41. The second insulating film 42 may include at least one among a silicon oxide film, a silicon nitride film, and a silicon oxynitride film. The interlayer insulating film 40 preferably includes a silicon oxide film. The second insulating film 42 covers the first principal surface 3 with the first insulating film 41 interposed therebetween in the active region 10 and the outer peripheral region 11.

The second insulating film 42 covers the plurality of gate structures 35 in the active region 10. The second insulating film 42 covers the plurality of field regions 38 with the first insulating film 41 interposed therebetween in the outer peripheral region 11. In this embodiment, the second insulating film 42 is continuous to the peripheral edges of the first principal surface 3. As a matter of course, the second insulating film 42 may be formed at intervals inward from the peripheral edges of the first principal surface 3 and expose the peripheral edge portions of the first principal surface 3 together with the first insulating film 41.

The semiconductor device 1A includes a plurality of contact openings 43 formed in the interlayer insulating film 40. The plurality of contact openings 43 include the plurality of contact openings 43 (not shown) that expose the plurality of gate structures 35 (the gate electrodes 37) and the plurality of contact openings 43 that expose the plurality of source regions 33. The plurality of contact openings 43 for the source regions 33 are formed in regions between the plurality of adjacent gate structures 35 and expose the plurality of source regions 33 and the plurality of contact regions 34.

Referring to FIG. 1, the semiconductor device 1A includes a gate pad 45 disposed on the interlayer insulating film 40. The gate pad 45 is an electrode to which the gate potential is applied from an exterior. The gate pad 45 may be referred to as a “gate pad electrode,” a “first pad electrode,” or the like. The gate pad 45 may have a laminated structure including a Ti-based metal film and an Al-based metal film laminated in that order from the interlayer insulating film 40 side.

In this embodiment, the gate pad 45 is disposed on a portion of the interlayer insulating film 40 that covers the active region 10. The gate pad 45 may be disposed at an interval to the active region 10 side from the outer peripheral region 11. In this embodiment, the gate pad 45 is disposed at a peripheral edge portion of the active region 10 in plan view.

FIG. 1 shows an example in which the gate pad 45 is disposed in a region along the central portion of the second side surface 5B in the peripheral edge portion of the active region 10. As a matter of course, the gate pad 45 may be disposed in a region along any of central portions of the first to fourth side surfaces 5A to 5D. As a matter of course, the gate pad 45 may be disposed at any corner portion of the active region 10 in plan view. Also, the gate pad 45 may be disposed at a central portion of the active region 10 in plan view. In this embodiment, the gate pad 45 is formed in a quadrilateral shape in plan view.

The semiconductor device 1A includes at least one (in this embodiment, a plurality) of gate wirings 46 that is led out onto the interlayer insulating film 40 from the gate pad 45. The gate wiring 46 may be referred to as a “wiring,” a “wiring electrode,” or the like. The plurality of gate wirings 46 may have a laminated structure including a Ti-based metal film and an Al-based metal film laminated in that order from the interlayer insulating film 40 side. In this embodiment, the plurality of gate wirings 46 include a first gate wiring 46A and a second gate wiring 46B.

The first gate wiring 46A is led out toward the first side surface 5A side from the gate pad 45 and extends in a line shape along the peripheral edge of the active region 10 such as to intersect (specifically, be orthogonal to) portions (specifically, one end portions) of the plurality of gate structures 35. The first gate wiring 46A penetrates through the interlayer insulating film 40 through the plurality of contact openings 43 and is electrically connected to the one end portions of the plurality of gate structures 35.

The second gate wiring 46B is led out toward the third side surface 5C side from the gate pad 45, and extends in a line shape along the peripheral edge of the active region 10 such as to intersect (specifically, be orthogonal to) portions (specifically, the other end portions) of the plurality of gate structures 35. The second gate wiring 46B penetrates through the interlayer insulating film 40 through the plurality of contact openings 43 and is electrically connected to the other end portions of the plurality of gate structures 35.

The semiconductor device 1A includes a source pad 47 disposed on the interlayer insulating film 40 at intervals from the gate pad 45 and the gate wirings 46. The source pad 47 is an electrode to which a source potential is applied from an exterior. The source pad 47 may be referred to as a “source pad electrode,” a “second pad electrode,” or the like. The source pad 47 may have a laminated structure including a Ti-based metal film and an Al-based metal film laminated in that order from the interlayer insulating film 40 side.

The source pad 47 is disposed on a portion of the interlayer insulating film 40 that covers the active region 10. The source pad 47 may be disposed at an interval to the active region 10 side from the outer peripheral region 11. In this embodiment, the source pad 47 is formed in a polygonal shape having a recess portion recessed along the gate pad 45 in plan view. As a matter of course, the source pad 47 may be formed in a quadrilateral shape in plan view.

The source pad 47 penetrates through the interlayer insulating film 40 through the plurality of contact openings 43 and is electrically connected to the plurality of body regions 32, the plurality of source regions 33, and the plurality of contact regions 34. That is, the source pad 47 is electrically connected to the plurality of second pillar regions 12 through the plurality of body regions 32.

Referring to FIG. 2, the semiconductor device 1A includes a drain pad 48 that covers the second principal surface 4. The drain pad 48 is an electrode to which a drain potential is applied from an exterior. The drain pad 48 may be referred to as a “drain pad electrode,” a “third pad electrode,” or the like. The drain pad 48 forms an ohmic contact with the base layer 6 exposed from the second principal surface 4. That is, the drain pad 48 is electrically connected to the laminated portion 7 (the drift region 8 and the plurality of first pillar regions 13) through the base layer 6.

The drain pad 48 may cover an entirety of the second principal surface 4 such as to be continuous to the peripheral edges (the first to fourth side surfaces 5A to 5D) of the chip 2. The drain pad 48 may cover the second principal surface 4 at intervals inward from the peripheral edges of the chip 2 such as to expose the peripheral edge portions of the chip 2.

A breakdown voltage applicable between the source pad 47 and the drain pad 48 (between the first principal surface 3 and the second principal surface 4) may be not less than 500 V and not more than 3000 V. The breakdown voltage may have a value belonging to any one range among not less than 500 V and not more than 1000 V, exceeding 1000 V and not more than 1500 V, exceeding 1500 V and not more than 2000 V, exceeding 2000 V and not more than 2500 V, and exceeding 2500 V and not more than 3000 V.

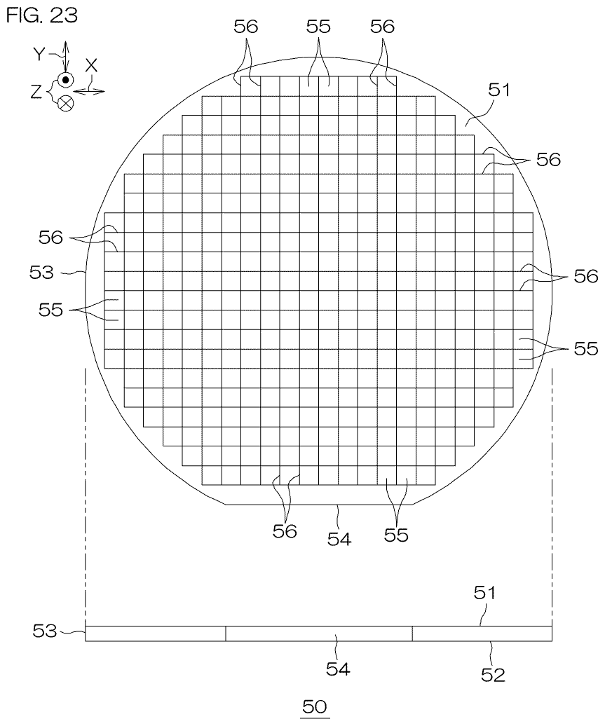

FIG. 23 is a schematic view showing a wafer 50 used in manufacture of the semiconductor device 1A. The wafer 50 is a base material of the base layer 6 and contains an SiC monocrystal. The wafer 50 is formed in a flat disk shape. As a matter of course, the wafer 50 may be formed in a flat rectangular parallelepiped shape instead. The wafer 50 has a first wafer principal surface 51 on one side, a second wafer principal surface 52 on the other side, and a wafer side surface 53 connecting the first wafer principal surface 51 and the second wafer principal surface 52.

The first wafer principal surface 51 corresponds to the upper end of the base layer 6, and the second wafer principal surface 52 corresponds to a lower end of the base layer 6. The first wafer principal surface 51 and the second wafer principal surface 52 are formed by c-planes of the SiC monocrystal. The first wafer principal surface 51 is formed by a silicon plane of the SiC monocrystal, and the second wafer principal surface 52 is formed by a carbon plane of the SiC monocrystal. The wafer 50 (the first wafer principal surface 51 and the second wafer principal surface 52) has the off direction Doff and the off angle θoff described above.

The wafer 50 has, on the wafer side surface 53, a mark 54 that indicates a crystal orientation of the SiC monocrystal. The mark 54 may include either or both of an orientation flat and an orientation notch. The orientation flat is constituted of a notched portion that is notched rectilinearly in plan view. The orientation notch is constituted of a notched portion that is notched in a recessed shape (for example, a tapered shape) toward a central portion of the first wafer principal surface 51 in plan view.

The mark 54 may include either or both of a first orientation flat that extends in the m-axis direction and a second orientation flat that extends in the a-axis direction. The mark 54 may include either or both of an orientation notch that is recessed in the m-axis direction and an orientation notch that is recessed in the a-axis direction. FIG. 23 shows the orientation flat extending in the m-axis direction in plan view.

For example, a plurality of device regions 55 and a plurality of intended cutting lines 56 are set by alignment marks, etc., in the wafer 50. Each of the device regions 55 is a region corresponding to the semiconductor device 1A. The plurality of device regions 55 are each set in a quadrilateral shape in plan view.

In this embodiment, the plurality of device regions 55 are set in a matrix along the first direction X and the second direction Y. The plurality of device regions 55 are each set at intervals inward from a peripheral edge of the first wafer principal surface 51 in plan view. The plurality of intended cutting lines 56 are set in a lattice extending along the first direction X and the second direction Y such as to demarcate the plurality of device regions 55.

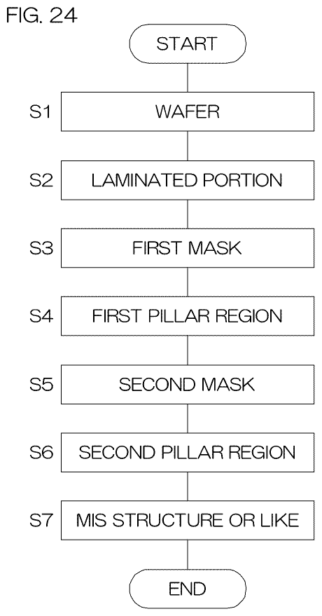

FIG. 24 is a flowchart showing a manufacturing method example of the semiconductor device 1A. FIGS. 25A to 25D are sectional perspective views showing the manufacturing method example of the semiconductor device 1A. FIGS. 25A to 25D show sectional perspective views of a portion of the active region 10 of the single device region 55.

First, referring to FIG. 25A, a step of preparing the wafer 50 described above is performed (step S1 in FIG. 24).

Next, referring to FIG. 25B, a step of forming the n-type laminated portion 7 is performed (step S2 in FIG. 24). The laminated portion 7 is formed with the first wafer principal surface 51 (the wafer 50) as a starting point by an epitaxial growth method while adding n-type impurity ions. The impurity ions used are at least one type of pentavalent element, preferably nitrogen. At this time point, the entire laminated portion 7 (the active region 10 and the outer peripheral region 11) is formed as the drift region 8. Therefore, the laminated portion 7 may have a concentration gradient of the n-type impurity concentration represented by the drift profile 22 or the drift profile 23 shown in FIG. 6.

Next, referring to FIG. 25C, a step of forming a first mask 60 having a predetermined pattern is performed (step S3 in FIG. 24). The first mask 60 is preferably an organic mask (resist mask). The first mask 60 is disposed on the first principal surface 3 of the laminated portion 7, and has a plurality of first openings 61 that expose regions where the plurality of first pillar regions 13 are to be formed in the laminated portion 7. The plurality of first openings 61 are formed at intervals in the first direction X and are each demarcated in a band shape extending in the second direction Y. That is, the plurality of first openings 61 have an extension direction extending along the off direction Doff in plan view.

Next, referring to FIG. 25C, a step of forming the plurality of first pillar regions 13 is performed (step S4 in FIG. 24). The step of forming the plurality of first pillar regions 13 includes an ion implantation step of a pentavalent element (n-type impurity) into the laminated portion 7. The impurity ions used are at least one type of pentavalent element, preferably phosphorus. As the ion implantation step, for example, a random implantation method, a channeling implantation method, or the like can be applied. At this time point, regions (for example, regions in which the second pillar regions 12 are to be formed) of the laminated portion 7 covered with the first mask 60 remain as the drift region 8.

Next, referring to FIG. 25D, a step of forming a second mask 62 having a predetermined pattern is performed (step S5 in FIG. 24). The second mask 62 is preferably an organic mask (resist mask). The second mask 62 is disposed on the first principal surface 3 of the laminated portion 7, and has a plurality of second openings 63 that expose regions where the plurality of second pillar regions 12 are to be formed in the laminated portion 7. The plurality of second openings 63 are formed at intervals in the first direction X and are each demarcated in a band shape extending in the second direction Y. That is, the plurality of second openings 63 have an extension direction extending along the off direction Doff in plan view.

Next, referring to FIG. 25D, a step of forming the plurality of second pillar regions 12 is performed (step S6 in FIG. 24). The step of forming the plurality of second pillar regions 12 includes an ion implantation step of a trivalent element (p-type impurity) into the laminated portion 7. The impurity ions used are at least one type of trivalent element, preferably aluminum. As the ion implantation step, for example, a random implantation method, a channeling implantation method, or the like can be applied. As a result, the second pillar regions 12 are formed in the drift region 8 exposed from the second openings 63.

Thereafter, the MIS structure 31, the plurality of field regions 38, the interlayer insulating film 40, the gate pad 45, the gate wiring 46, the source pad 47, the drain pad 48, and the like are formed (step S7 in FIG. 24). Then, the wafer 50 is cut along the plurality of intended cutting lines 56. As a result, a plurality of the semiconductor devices 1A are manufactured from the single wafer 50.

According to this method, when the first pillar regions 13 shown in FIG. 25C are formed, the portions of the drift region 8 where the second pillar regions 12 are to be formed are covered with the first mask 60. As a result, n-type impurity ions can be prevented from being newly implanted into the drift region 8, so that the drift concentration of the drift region 8 can be maintained.

In addition, since the drift region 8 can be protected by the first mask 60 from the irradiation of the n-type impurity ions, it is possible to prevent crystal defects 64 (damage) generated in the first pillar regions 13 from being formed in the regions where the second pillar regions 12 are to be formed. As a result, since the second pillar regions 12 can be formed by implantation of p-type impurity ions into the drift region 8 with comparatively little damage, the depth of the second pillar regions 12 can be easily controlled.

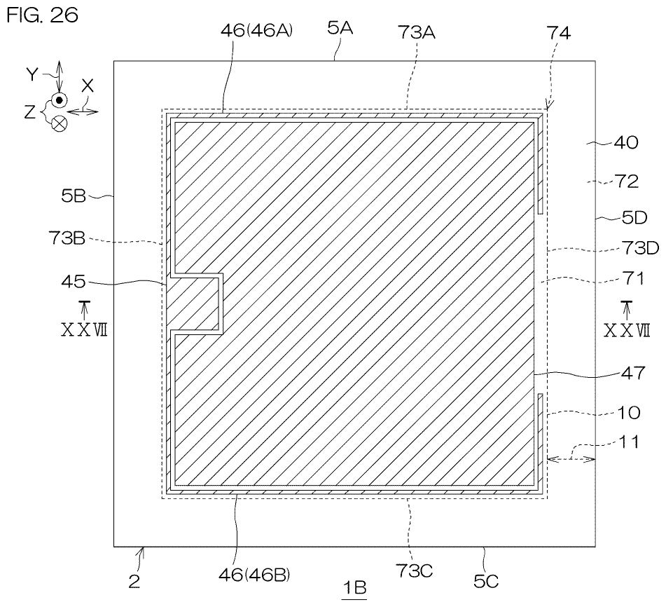

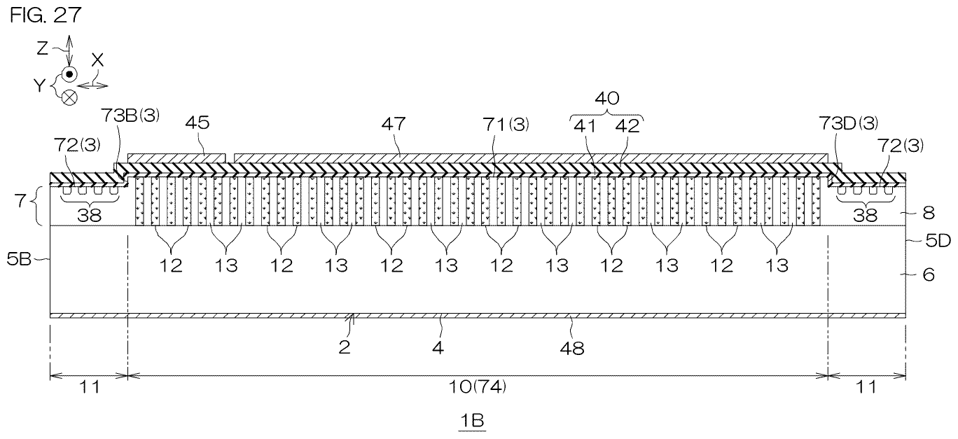

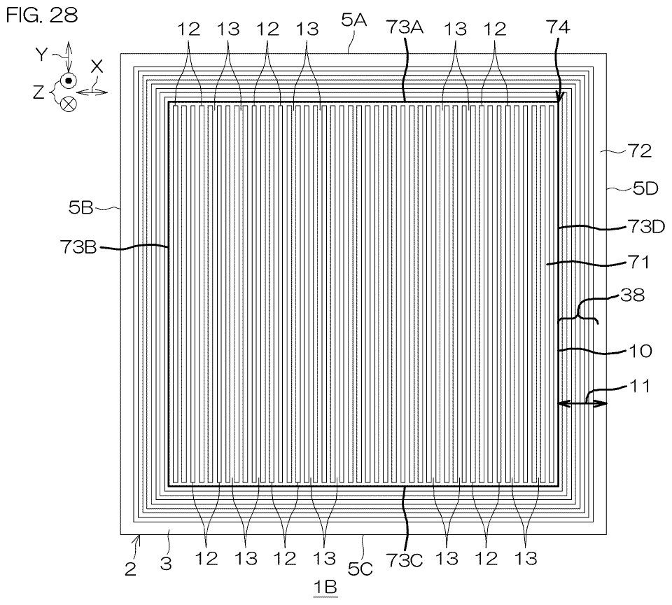

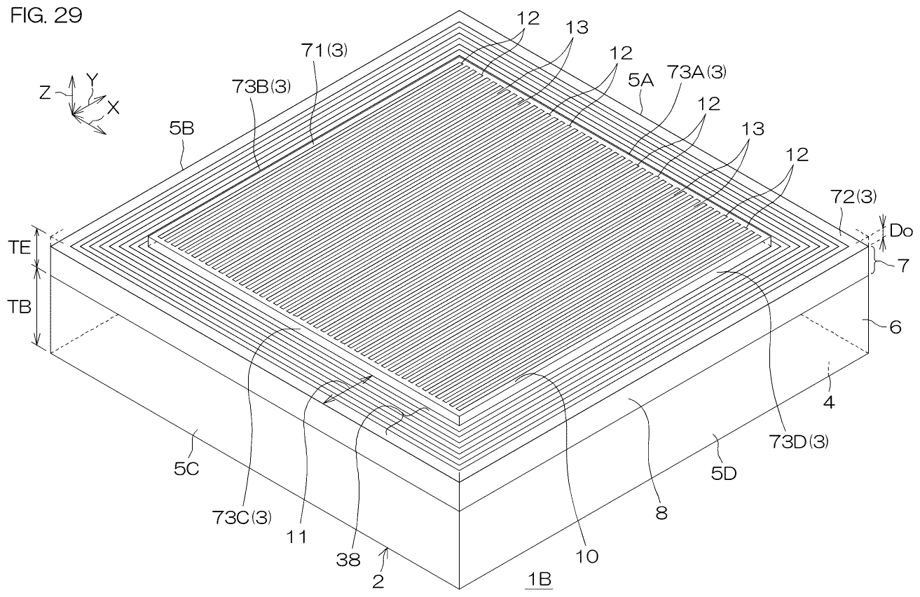

FIG. 26 is a plan view showing a semiconductor device 1B according to a second preferred embodiment. FIG. 27 is a sectional view taken along line XXVII-XXVII shown in FIG. 26. FIG. 28 is a plan view showing the layout example of the chip 2. FIG. 29 is a perspective view showing the layout example of the chip 2.

Referring to FIGS. 26 to 29, the semiconductor device 1B includes the chip 2, the base layer 6, the laminated portion 7, the active region 10, and the outer peripheral region 11 as in the case of the semiconductor device 1A.

In this embodiment, the semiconductor device 1B includes an active surface 71, an outer surface 72, and first to fourth connecting surfaces 73A to 73D that are formed in the first principal surface 3. The active surface 71, the outer surface 72, and the first to fourth connecting surfaces 73A to 73D demarcate an active mesa 74 in the first principal surface 3.

The active surface 71 may be referred to as a “first surface portion,” the outer surface 72 may be referred to as a “second surface portion,” the first to fourth connecting surfaces 73A to 73D may be referred to as “connecting surface portions,” and the active mesa 74 may be referred to as a “mesa portion.” The active surface 71, the outer surface 72, and the first to fourth connecting surfaces 73A to 73D (that is, the active mesa 74) may be considered as components of the chip 2 (the first principal surface 3).

The active surface 71 is formed in the active region 10. That is, the active surface 71 is formed at intervals inward from the peripheral edges (the first to fourth side surfaces 5A to 5D) of the first principal surface 3. The active surface 71 has a flat surface extending in the first direction X and the second direction Y. In this embodiment, the active surface 71 is formed by the c-plane (Si plane). In this embodiment, the active surface 71 is formed in a quadrilateral shape having four sides parallel to the first to fourth side surfaces 5A to 5D in plan view.

The outer surface 72 is formed in the outer peripheral region 11. That is, the outer surface 72 is formed outside the active surface 71. The outer surface 72 is recessed in the thickness direction of the chip 2 (toward the second principal surface 4 side) with respect to the active surface 71. The outer surface 72 extends in a band shape along the active surface 71 in plan view, and is formed in an annular shape (specifically, a quadrilateral annular shape) surrounding the active surface 71.

The outer surface 72 has a flat surface extending in the first direction X and the second direction Y, and is formed substantially parallel to the active surface 71. In this embodiment, the outer surface 72 is formed by the c-plane (Si plane). The outer surface 72 is continuous to the first to fourth side surfaces 5A to 5D. The outer surface 72 has an outer peripheral depth DO.

The outer peripheral depth DO may be not less than 0.1 μm and not more than 2 μm. The outer peripheral depth DO may have a value belonging to any one range among not less than 0.1 μm and not more than 0.25 μm, exceeding 0.25 μm and not more than 0.5 μm, exceeding 0.5 μm and not more than 0.75 μm, exceeding 0.75 μm and not more than 1 μm, exceeding 1 μm and not more than 1.5 μm, and exceeding 1.5 μm and not more than 2 μm. The outer peripheral depth DO is preferably not less than 0.1 μm and not more than 1.5 μm.

The first to fourth connecting surfaces 73A to 73D extend in the vertical direction Z and connect the active surface 71 and the outer surface 72. The first connecting surface 73A is positioned at the first side surface 5A side, the second connecting surface 73B is positioned at the second side surface 5B side, the third connecting surface 73C is positioned at the third side surface 5C side, and the fourth connecting surface 73D is positioned at the fourth side surface 5D side. The first connecting surface 73A and the third connecting surface 73C extend in the first direction X and are opposed in the second direction Y. The second connecting surface 73B and the fourth connecting surface 73D extend in the second direction Y and are opposed in the first direction X.

The first to fourth connecting surfaces 73A to 73D may extend substantially vertically between the active surface 71 and the outer surface 72 such as to demarcate the active mesa 74 of a quadrilateral columnar shape. The first to fourth connecting surfaces 73A to 73D may be inclined obliquely downward from the active surface 71 toward the outer surface 72 such as to demarcate the active mesa 74 of a quadrilateral pyramid shape instead. The active mesa 74 is thus demarcated in a projecting shape in the laminated portion 7 in the first principal surface 3.

The semiconductor device 1B includes the plurality of second pillar regions 12 of the p-type formed in the laminated portion 7 in the active region 10. The plurality of second pillar regions 12 are formed in the same layout as in the case of the semiconductor device 1A.

The plurality of second pillar regions 12 may have at least one of the plurality of features shown in the basic embodiment and the first to eleventh configuration examples. The plurality of second pillar regions 12 may have a feature in which a plurality of (not less than two) features shown in the basic embodiment and the first to eleventh configuration examples described above are combined.

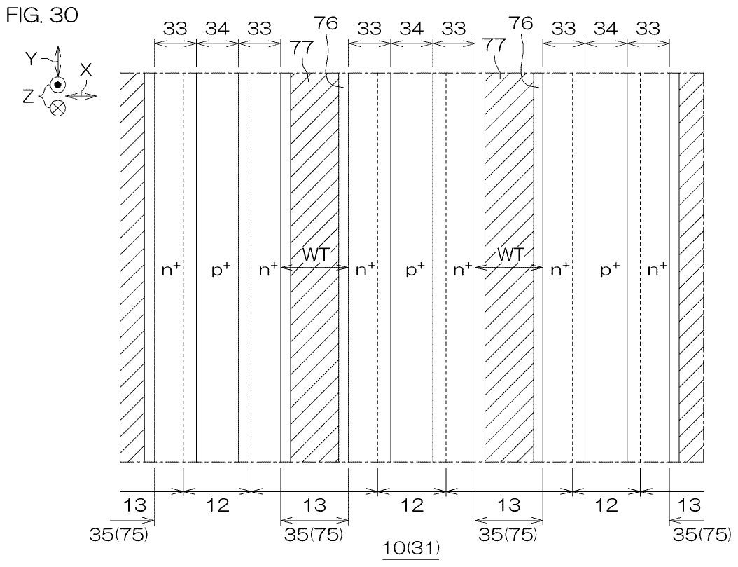

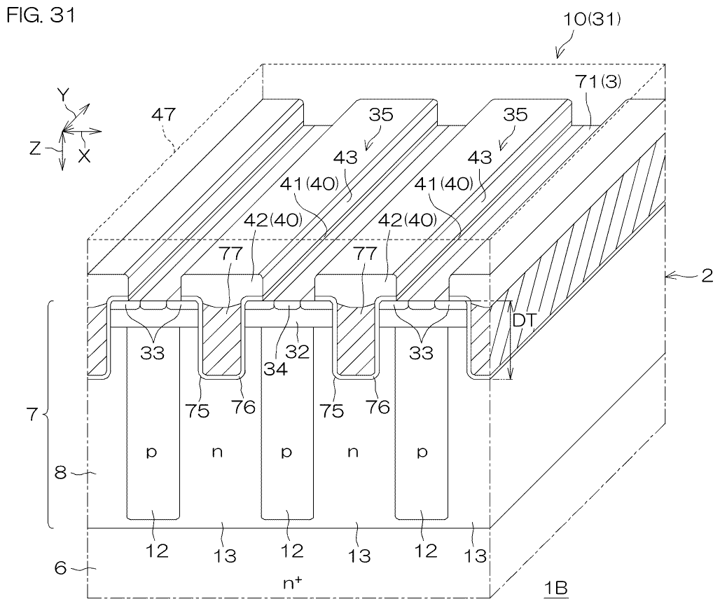

FIG. 30 is a plan view showing a principal portion of the active region 10. FIG. 31 is a sectional perspective view showing the gate structure 35 according to the first configuration example. Referring to FIGS. 30 and 31, the semiconductor device 1B includes the MIS structure 31 formed in the active region 10. The following arrangement will be described as components of the semiconductor device 1B, but are also components of the MIS structure 31.

The semiconductor device 1B includes the body region 32 of the p-type formed in the surface layer portion of the first principal surface 3 (the active surface 71). In this embodiment, the body region 32 is formed in a layered shape extending along the active surface 71. The body region 32 may be formed in an entirety of the active surface 71 and may be exposed from the first to fourth connecting surfaces 73A to 73D.

The body region 32 is formed at an interval to the active surface 71 side from the lower end of the laminated portion 7, and overlaps the plurality of second pillar regions 12 in the lamination direction. The body region 32 preferably overlaps all the second pillar regions 12 in the lamination direction. It is preferable that the body region 32 is formed at an interval to the active surface 71 side from a depth position of the outer surface 72, and is exposed from the first principal surface 3.

When the plurality of second pillar regions 12 are formed at intervals from the first principal surface 3, the body region 32 is formed in a region between the active surface 71 and the second upper end portions 12b (see FIG. 11) of the plurality of second pillar regions 12. The body region 32 is preferably connected to the plurality of second pillar regions 12 (the second upper end portions 12b).

The body region 32 may have a p-type impurity concentration of not less than 1×10¹⁵ cm⁻³ and not more than 1×10¹⁸ cm⁻³ as a peak value.

The p-type impurity concentration of the body region 32 is preferably adjusted by at least one type of trivalent element. The trivalent element of the body region 32 may be the same type as a trivalent element of the second pillar region 12 or the like or may be a type different from the trivalent element of the second pillar region 12 or the like. The trivalent element of the body region 32 may be at least one type among boron, aluminum, gallium, and indium.

The semiconductor device 1B includes the plurality of gate structures 35 of a trench electrode type that are formed in the first principal surface 3 (the active surface 71) in the active region 10. The gate structure 35 may be referred to as a “trench gate structure.” The gate potential is applied as the control potential to the plurality of gate structures 35. The plurality of gate structures 35 control the inversion and the non-inversion of the channels (the current paths) inside the body region 32 in response to the gate potential.

The plurality of gate structures 35 are disposed at intervals inward from peripheral edges of the active surface 71 (from the first to fourth connecting surfaces 73A to 73D) in the active region 10. In this embodiment, the plurality of gate structures 35 are aligned as stripes extending in the extension direction of the plurality of second pillar regions 12. Specifically, in this embodiment, the plurality of gate structures 35 are aligned at intervals in the first direction X, and each formed in a band shape extending in the second direction Y.

That is, the plurality of gate structures 35 are aligned at intervals in the m-axis direction of the SiC monocrystal and extend in the a-axis direction of the SiC monocrystal. In other words, the extension direction of the plurality of gate structures 35 coincides with the off direction Doff of the SiC monocrystal. Also, the extension direction of the plurality of gate structures 35 coincides with the extension direction of the plurality of second pillar regions 12.

In this embodiment, the plurality of gate structures 35 are disposed to be shifted from the plurality of second pillar regions 12 toward the plurality of first pillar regions 13. Specifically, the plurality of gate structures 35 penetrate through the body region 32 at intervals from the plurality of second pillar regions 12, and are disposed in the plurality of first pillar regions 13 in one-to-one correspondence. That is, the plurality of gate structures 35 face the plurality of second pillar regions 12 in the horizontal direction.

The plurality of gate structures 35 are formed at intervals to the active surface 71 side from the lower ends of the plurality of first pillar regions 13, and face the plurality of base layers 6 with portions of the plurality of first pillar regions 13 interposed therebetween. The plurality of gate structures 35 are preferably formed at intervals to the active surface 71 side from the intermediate portions in the thickness range of the plurality of second pillar regions 12. As a matter of course, the plurality of gate structures 35 may be formed at depth positions crossing the intermediate portions in the thickness range of the plurality of second pillar regions 12.

Each of the gate structures 35 has a trench width WT in the first direction X and a trench depth DT in the vertical direction Z. The trench width WT is less than the second pitch P2. The trench depth DT is less than the second thickness T2 of the second pillar region 12. The trench depth DT is preferably substantially equal to the outer peripheral depth DO described above. As a matter of course, the trench depth DT may be not less than the outer peripheral depth DO or may be less than the outer peripheral depth DO.

The trench width WT may be not less than 0.1 μm and not more than 5 μm. The trench width WT may have a value belonging to any one range among not less than 0.1 μm and not more than 0.25 μm, exceeding 0.25 μm and not more than 0.5 μm, exceeding 0.5 μm and not more than 0.75 μm, exceeding 0.75 μm and not more than 1 μm, exceeding 1 μm and not more than 1.5 μm, exceeding 1.5 μm and not more than 2 μm, exceeding 2 μm and not more than 2.5 μm, exceeding 2.5 μm and not more than 3 μm, exceeding 3 μm and not more than 3.5 μm, exceeding 3.5 μm and not more than 4 μm, exceeding 4 μm and not more than 4.5 μm, and exceeding 4.5 μm and not more than 5 μm.

The trench depth DT may be not less than 0.1 μm and not more than 5 μm. The trench depth DT may have a value belonging to any one range among not less than 0.1 μm and not more than 0.25 μm, exceeding 0.25 μm and not more than 0.5 μm, exceeding 0.5 μm and not more than 1 μm, exceeding 1 μm and not more than 1.5 μm, exceeding 1.5 μm and not more than 2 μm, exceeding 2 μm and not more than 3 μm, exceeding 3 μm and not more than 4 μm, and exceeding 4 μm and not more than 5 μm. The trench depth DT is preferably not less than 0.1 μm and not more than 1.5 μm.

Each of the gate structures 35 includes a trench 75, an insulating film 76, and an embedded electrode 77. The trench 75 is formed in the active surface 71 and demarcates wall surfaces of the gate structure 35. The insulating film 76 covers wall surfaces of the trench 75. The insulating film 76 may include at least one among a silicon oxide film, a silicon nitride film, and a silicon oxynitride film.

In this embodiment, the insulating film 76 has a single layer structure constituted of the silicon oxide film. The insulating film 76 particularly preferably includes the silicon oxide film that consists of the oxide of the chip 2. The embedded electrode 77 is embedded in the trench 75 with the insulating film 76 interposed therebetween, and faces the channel with the insulating film 76 interposed therebetween. The embedded electrode 77 may contain a conductive polysilicon of the p-type or the n-type.

The semiconductor device 1B includes the plurality of source regions 33 formed on both sides of the plurality of gate structures 35 in the surface layer portion of the first principal surface 3 (the active surface 71). The plurality of source regions 33 are formed in the surface layer portion of the body region 32. The plurality of source regions 33 have an n-type impurity concentration higher than the n-type impurity concentration of the first pillar region 13 and the drift region 8 of the laminated portion 7. The plurality of source regions 33 may have an n-type impurity concentration of not less than 1×10¹⁸ cm⁻³ and not more than 1×10²¹ cm⁻³ as a peak value.

The plurality of source regions 33 extend in band shapes along the corresponding gate structure 35 in plan view. The plurality of source regions 33 are formed at intervals to the active surface 71 side from the bottom portion of the body region 32, and face the first pillar region 13 with a portion of the body region 32 interposed therebetween in the lamination direction. The plurality of source regions 33 demarcate channels (current paths) extending along the wall surfaces of the corresponding gate structure 35 together with the plurality of first pillar regions 13 positioned immediately below.

The plurality of source regions 33 may face the second pillar region 12 with a portion of the body region 32 interposed therebetween in the lamination direction. As a matter of course, the plurality of source regions 33 may be formed at intervals from the second pillar region 12 to the first pillar region 13 side (the gate structure 35 side) such as not to face the second pillar region 12 in the lamination direction.

The semiconductor device 1B includes the plurality of contact regions 34 that are formed in regions between the plurality of gate structures 35 in the surface layer portion of the first principal surface 3 (the active surface 71). The plurality of contact regions 34 are formed in the surface layer portion of the body region 32.

The plurality of contact regions 34 have a p-type impurity concentration (peak value) higher than the p-type impurity concentration (peak value) of the plurality of body regions 32. The p-type impurity concentration (peak value) of the plurality of contact regions 34 is higher than the p-type impurity concentration (peak value) of the plurality of second pillar regions 12. The plurality of contact regions 34 may have a p-type impurity concentration of not less than 1×10¹⁸ cm⁻³ and not more than 1×10²¹ cm⁻³ as a peak value.

The plurality of contact regions 34 are interposed in regions between the plurality of source regions 33 adjacent to each other, and extend in band shapes along the plurality of gate structures 35. The plurality of contact regions 34 are formed at intervals to the active surface 71 side from the bottom portion of the body region 32, and face the plurality of second pillar regions 12 with a portion of the body region 32 interposed therebetween in the lamination direction.

The plurality of contact regions 34 may face the first pillar regions 13 with a portion of the body region 32 interposed therebetween in the lamination direction. As a matter of course, the plurality of contact regions 34 may be formed at intervals from the first pillar regions 13 toward the second pillar regions 12 such as not to face the first pillar regions 13 in the lamination direction.

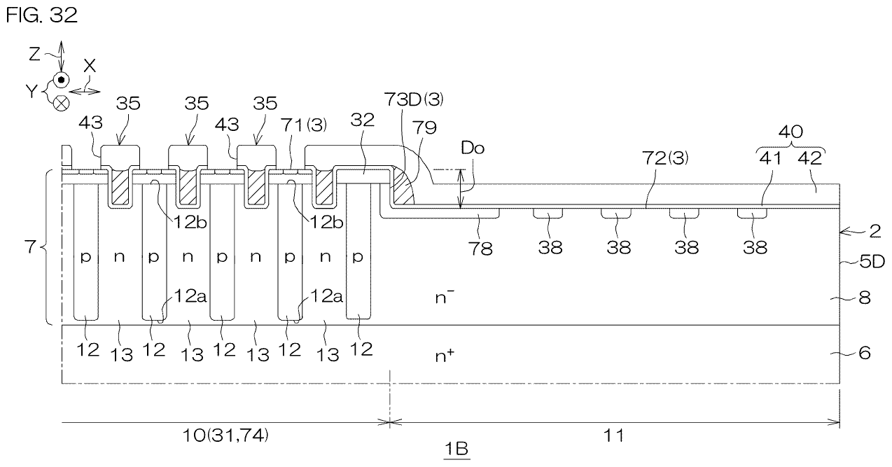

Hereinafter, an arrangement on the outer peripheral region 11 side will be described. FIG. 32 is a sectional view showing a principal portion of the outer peripheral region 11. Referring to FIG. 32, the semiconductor device 1B includes a well region 78 of the p-type formed in a surface layer portion of the outer surface 72. In plan view, the well region 78 is formed at intervals to the active surface 71 side from peripheral edges of the outer surface 72 (from the first to fourth side surfaces 5A to 5D) and extends in a band shape along the active surface 71.

In this embodiment, the well region 78 is formed in an annular shape (specifically, a quadrilateral annular shape) surrounding the active surface 71 in plan view. The well region 78 is led out from the surface layer portion of the outer surface 72 to the first to fourth connecting surfaces 73A to 73D sides and extends along surface layer portions of the first to fourth connecting surfaces 73A to 73D. The well region 78 is electrically connected to the body region 32 in a surface layer portion of the active surface 71. The well region 78 is formed at an interval to the outer surface 72 side from the lower end of the laminated portion 7, and faces the base layer 6 with a portion of the drift region 8 interposed therebetween.

A bottom portion of the well region 78 is positioned further to the lower end side of the laminated portion 7 than a bottom wall of the gate structure 35. The bottom portion of the well region 78 is preferably positioned on the outer surface 72 side with respect to the second lower end portions 12a of the plurality of second pillar regions 12. The bottom portion of the well region 78 is particularly preferably positioned on the outer surface 72 side with respect to the intermediate portions in the thickness range of the plurality of second pillar regions 12.

The well region 78 may have a p-type impurity concentration of not less than 1×10¹⁵ cm⁻³ and not more than 1×10¹⁸ cm⁻³ as a peak value.

The well region 78 has a p-type impurity concentration lower than the p-type impurity concentration of the contact region 34. The p-type impurity concentration of the well region 78 is higher than the p-type impurity concentration of the body region 32. As a matter of course, the p-type impurity concentration of the well region 78 may be lower than that of the body region 32. The well region 78 forms a pn junction portion with the drift region 8.

The p-type impurity concentration of the well region 78 is preferably adjusted by at least one type of trivalent element. The trivalent element of the well region 78 may be the same type as a trivalent element of the second pillar region 12 or the like or may be a type different from the trivalent element of the second pillar region 12 or the like. The trivalent element of the well region 78 may be at least one type among boron, aluminum, gallium, and indium.

The semiconductor device 1B includes at least one (preferably, not less than 2 and not more than 20) of the field regions 38 of the p-type formed in the surface layer portion of the outer surface 72 in the outer peripheral region 11. The plurality of field regions 38 are formed in the surface layer portion of the outer surface 72 in the same manner as in the case of the semiconductor device 1A.

In this embodiment, the plurality of field regions 38 are aligned at intervals from the peripheral edges of the active surface 71 (from the first to fourth connecting surfaces 73A to 73D) and from the peripheral edges (the first to fourth side surfaces 5A to 5D) of the chip 2. Specifically, the plurality of field regions 38 are aligned at intervals to the peripheral edge sides of the outer surface 72 from the well region 78.

The plurality of field regions 38 extend in band shapes along the active surface 71 in plan view, and are formed in annular shapes (specifically, quadrilateral annular shapes) surrounding the active surface 71. The plurality of field regions 38 are formed at intervals to the outer surface 72 side from a bottom portion of the laminated portion 7 (the drift region 8), and face the base layer 6 with a portion of the drift region 8 interposed therebetween. The plurality of field regions 38 are positioned further to the lower end side of the drift region 8 than a bottom portion of the gate structure 35.

The semiconductor device 1B includes the above-described interlayer insulating film 40 covering the first principal surface 3. The interlayer insulating film 40 has the laminated structure that includes the first insulating film 41 and the second insulating film 42. In this embodiment, the first insulating film 41 selectively covers the active surface 71, the outer surface 72, and the first to fourth connecting surfaces 73A to 73D. On the active surface 71, the first insulating film 41 is connected to the insulating film 76 and exposes the embedded electrode 77.

On the outer surface 72, the first insulating film 41 covers the well region 78 and the plurality of field regions 38. In this embodiment, the first insulating film 41 is continuous to the first to fourth side surfaces 5A to 5D. As a matter of course, the first insulating film 41 may be formed at intervals inward from the peripheral edges of the outer surface 72 and expose a second layer 9 from peripheral edge portions of the outer surface 72. The first insulating film 41 covers the well region 78 in the first to fourth connecting surfaces 73A to 73D.

In this embodiment, the second insulating film 42 selectively covers the active surface 71, the outer surface 72, and the first to fourth connecting surfaces 73A to 73D with the first insulating film 41 interposed therebetween. The second insulating film 42 covers the plurality of gate structures 35 in the active region 10. The second insulating film 42 covers the plurality of field regions 38 and the well region 78 with the first insulating film 41 interposed therebetween in the outer peripheral region 11. In this embodiment, the second insulating film 42 is continuous to the first to fourth side surfaces 5A to 5D. As a matter of course, the second insulating film 42 may be formed at intervals inward from the peripheral edges of the outer surface 72 and expose the laminated portion 7 from the peripheral edge portions of the outer surface 72 together with the first insulating film 41.

The semiconductor device 1B includes the plurality of contact openings 43 formed in the interlayer insulating film 40. The plurality of contact openings 43 include the plurality of contact openings 43 (not shown) that expose the plurality of gate structures 35 (the embedded electrodes 77) and the plurality of contact openings 43 that expose the plurality of source regions 33. The plurality of contact openings 43 for the source regions 33 are formed in regions between the plurality of adjacent gate structures 35 and expose the plurality of source regions 33 and the plurality of contact regions 34.

The semiconductor device 1B includes a side wall structure 79 that is disposed in the interlayer insulating film 40 such as to cover at least one of the first to fourth connecting surfaces 73A to 73D. The side wall structure 79 is disposed on the first insulating film 41 and is covered with the second insulating film 42. The side wall structure 79 moderates a level difference formed between the active surface 71 and the outer surface 72.

The side wall structure 79 is formed in a band shape extending along at least one of the first to fourth connecting surfaces 73A to 73D. In this embodiment, the side wall structure 79 is formed in an annular shape (specifically, a quadrilateral annular shape) extending along the first to fourth connecting surfaces 73A to 73D such as to surround the active surface 71 in plan view.

The side wall structure 79 may have a portion extending in a film shape along the outer surface 72 and a portion extending in a film shape along the first to fourth connecting surfaces 73A to 73D. In this embodiment, the side wall structure 79 is formed at an interval to the active surface 71 side from the innermost field region 38 and faces the well region 78 with the first insulating film 41 interposed therebetween in the horizontal directions and the lamination direction. The side wall structure 79 may face the body region 32 with the first insulating film 41 interposed therebetween.

As in the case of the semiconductor device 1A, the semiconductor device 1B includes the gate pad 45, the plurality of gate wirings 46, the source pad 47, and the drain pad 48. The drain pad 48 is formed in a configuration similar to the case of the first configuration example.

In this embodiment, the gate pad 45 is disposed on the active surface 71 at an interval from the outer surface 72 in plan view. The gate pad 45 is disposed in a region adjacent to a central portion of one side (in this embodiment, the second connecting surface 73B) of the active surface 71 in plan view. As a matter of course, the gate pad 45 may be disposed at a corner portion of the active surface 71 or a central portion of the active surface 71 in plan view.

In this embodiment, the plurality of gate wirings 46 are disposed on the active surface 71 at intervals from the outer surface 72 in plan view. The plurality of gate wirings 46 include the first gate wiring 46A and the second gate wiring 46B.

The first gate wiring 46A is led out toward the first connecting surface 73A side from the gate pad 45 and extends in a line shape along the peripheral edge of the active surface 71 such as to intersect (specifically, be orthogonal to) portions (specifically, one end portions) of the plurality of gate structures 35. The first gate wiring 46A penetrates through the interlayer insulating film 40 through the plurality of contact openings 43 and is electrically connected to the one end portions of the plurality of gate structures 35 (the embedded electrodes 77).

The second gate wiring 46B is led out toward the third connecting surface 73C side from the gate pad 45 and extends in a line shape along the peripheral edge of the active surface 71 such as to intersect (specifically, be orthogonal to) portions (specifically, other end portions) of the plurality of gate structures 35. The second gate wiring 46B penetrates through the interlayer insulating film 40 through the plurality of contact openings 43 and is electrically connected to the other end portions of the plurality of gate structures 35 (the embedded electrodes 77).

In this embodiment, the source pad 47 is disposed on the active surface 71 at an interval from the outer surface 72 in plan view. The source pad 47 penetrates through the interlayer insulating film 40 through the plurality of contact openings 43 and is electrically connected to the body region 32, the plurality of source regions 33, and the plurality of contact regions 34. That is, the source pad 47 is electrically connected to the plurality of second pillar regions 12 through the body region 32.

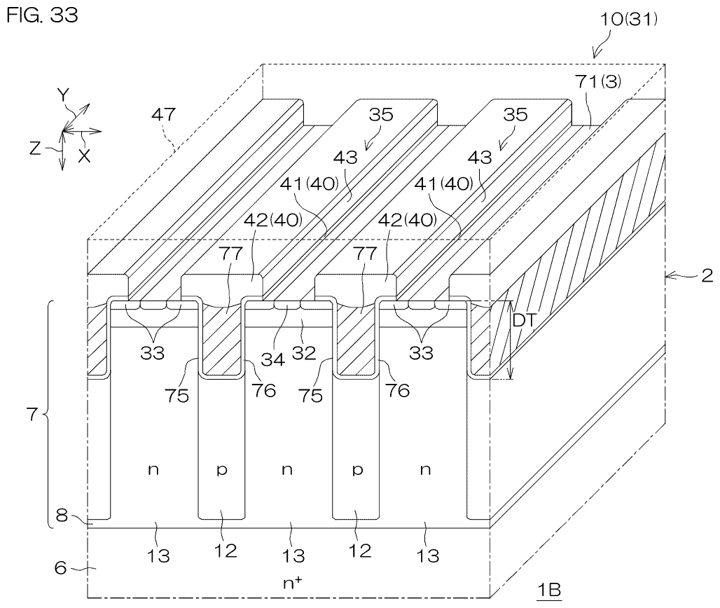

FIG. 33 is a sectional perspective view showing the gate structure 35 according to the second configuration example. The plurality of gate structures 35 according to the first configuration example described above are aligned such as to be shifted from the plurality of second pillar regions 12 toward the plurality of first pillar regions 13. On the other hand, referring to FIG. 33, the plurality of gate structures 35 according to the second configuration example are aligned such as to overlap the plurality of second pillar regions 12 in the lamination direction. The plurality of gate structures 35 overlap the plurality of second pillar regions 12 in one-to-one correspondence in the lamination direction.

Each of the plurality of gate structures 35 has a bottom wall connected to the corresponding second pillar region 12. Specifically, each of the plurality of gate structures 35 is formed to be wider than the corresponding second pillar region 12 and has the bottom wall connected to the corresponding second pillar region 12 and side walls each connected to the corresponding first pillar region 13.

That is, the embedded electrode 77 faces the corresponding second pillar region 12 with the insulating film 76 interposed therebetween in the lamination direction, and faces the corresponding first pillar regions 13 with the insulating film 76 interposed therebetween in the horizontal direction. The plurality of source regions 33 and the plurality of contact regions 34 described above each face the corresponding first pillar region 13 with a portion of the body region 32 interposed therebetween in the lamination direction.

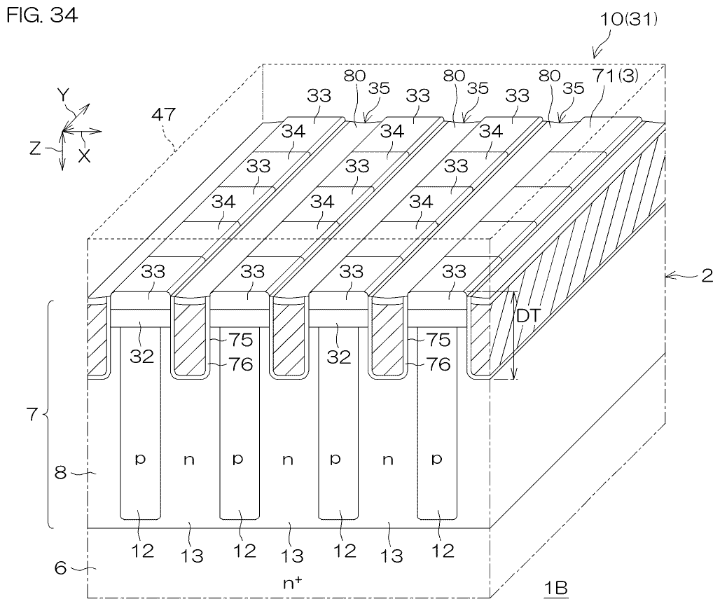

FIG. 34 is a sectional perspective view showing the gate structure 35 according to the third configuration example. With reference to FIG. 34, the plurality of gate structures 35 according to the third configuration example each have an arrangement that contributes to narrowing of pitch. The plurality of gate structures 35 according to the third configuration example is particularly effective in achieving narrowing of pitch of the second pillar regions 12. Although FIG. 34 shows an example in which the gate structure 35 according to the first configuration example is replaced with the gate structure 35 according to the third configuration example, the arrangement of the gate structure 35 according to the third configuration example is also applicable to the arrangement of the gate structure 35 according to the second configuration example.

The plurality of gate structures 35 each include the trench 75, the insulating film 76, the embedded electrode 77, and an embedded insulator 80. The trench 75 has the same configuration as in the case of the first configuration example. In this embodiment, the insulating film 76 is formed at an interval to the bottom wall side of the trench 75 from the first principal surface 3 (the active surface 71) and exposes the surface layer portion of the first principal surface 3 (the active surface 71) at an opening end of the trench 75. An upper end portion of the insulating film 76 is preferably positioned at the first principal surface 3 side with respect to an intermediate portion in a depth range of the trench 75.

In this embodiment, the embedded electrode 77 is embedded in the trench 75 at an interval to the bottom wall side of the trench 75 from the first principal surface 3 (the active surface 71) and, at the opening end of the trench 75, demarcates an opening recess recessed toward the bottom wall of the trench 75. At the opening end of the trench 75, the embedded electrode 77 exposes the surface layer portion of the first principal surface 3 (the active surface 71) and the upper end portion of the insulating film 76. An upper end portion of the embedded electrode 77 is preferably positioned at the first principal surface 3 side with respect to the intermediate portion in the depth range of the trench 75.

The embedded insulator 80 is embedded in the trench 75 (the opening recess) such as to expose the first principal surface 3 (the active surface 71) and, inside the trench 75, covers the insulating film 76 and the embedded electrode 77. The embedded insulator 80 is embedded in the trench 75 at an interval to the embedded electrode 77 side from the first principal surface 3 (the active surface 71) and, at the opening end of the trench 75, exposes the surface layer portion of the first principal surface 3 (the active surface 71).

An upper end portion of the embedded insulator 80 is preferably positioned at the first principal surface 3 side with respect to the intermediate portion in the depth range of the trench 75. The embedded insulator 80 may include at least one among a silicon oxide film, a silicon nitride film, and a silicon oxynitride film. The embedded insulator 80 preferably includes the silicon oxide film.

In this embodiment, the plurality of source regions 33 described above are respectively formed in regions between the plurality of gate structures 35 that are mutually adjacent in the surface layer portion of the first principal surface 3 (the active surface 71). The plurality of source regions 33 are aligned at intervals along the plurality of gate structures 35 such as to be connected to the plurality of gate structures 35 positioned on both sides.

Specifically, the plurality of source regions 33 at one side that are aligned along the side walls at one side of the gate structures 35 face, in one-to-one correspondence, the plurality of source regions 33 at the other side that are aligned along the side walls at the other side of the gate structures 35. That is, the plurality of source regions 33 are aligned in a matrix in plan view.

As a matter of course, the plurality of source regions 33 at the one side may face, in one-to-one correspondence, regions between the plurality of source regions 33 at the other side instead. That is, the plurality of source regions 33 may be aligned in a staggered arrangement in plan view. The plurality of source regions 33 have portions that are exposed from the side walls of the trenches 75 at the opening ends of the trenches 75 and face the embedded electrodes 77 and the embedded insulators 80 with the insulating films 76 interposed therebetween.

In this embodiment, the plurality of contact regions 34 described above are respectively formed in regions between the plurality of gate structures 35 that are mutually adjacent in the surface layer portion of the first principal surface 3 (the active surface 71). The plurality of contact regions 34 are aligned at intervals along the plurality of gate structures 35 such as to be connected to the plurality of gate structures 35 positioned on both sides.

Specifically, the plurality of contact regions 34 are aligned alternately with the plurality of source regions 33 along the plurality of gate structures 35. More specifically, the plurality of contact regions 34 at one side that are aligned along the side walls at one side of the gate structures 35 face, in one-to-one correspondence, the plurality of contact regions 34 at the other side that are aligned along the side walls at the other side of the gate structures 35. In addition, the plurality of source regions 33 are aligned in a matrix in plan view.

As a matter of course, the plurality of contact regions 34 at the one side may face, in one-to-one correspondence, regions (that is, the plurality of source regions 33) between the plurality of source regions 33 at the other side instead. That is, the plurality of contact regions 34 may be aligned in a staggered arrangement in plan view. The plurality of contact regions 34 have portions that are exposed from the side walls of the trenches 75 at the opening ends of the trenches 75 and face the embedded electrodes 77 and the embedded insulators 80 with the insulating films 76 interposed therebetween.

Although specific illustration is omitted, the interlayer insulating film 40 described above has the laminated structure that includes the first insulating film 41 and the second insulating film 42. As in the case of the first configuration example, the first insulating film 41 selectively covers the active surface 71, the outer surface 72, and the first to fourth connecting surfaces 73A to 73D.

In this embodiment, the first insulating film 41 covers peripheral edge portions of the active surface 71 and exposes the plurality of gate structures 35 altogether in an inner portion of the active surface 71. Specifically, the first insulating film 41 is connected to the insulating film 76 at both end portions of the plurality of gate structures 35 and exposes the embedded electrode 77. Also, the first insulating film 41 covers the outer surface 72 and the first to fourth connecting surfaces 73A to 73D in the same manner as in the case of the first configuration example.

As in the case of the first configuration example, the second insulating film 42 selectively covers the active surface 71, the outer surface 72, and the first to fourth connecting surfaces 73A to 73D with the first insulating film 41 interposed therebetween. In this embodiment, the second insulating film 42 covers the peripheral edge portions of the active surface 71 and exposes the plurality of gate structures 35 altogether in the inner portion of the active surface 71. Specifically, the second insulating film 42 enters into the trench 75 from above the first principal surface 3 (the active surface 71) at the both end portions of the plurality of gate structures 35, and is connected to the embedded insulator 80 inside the trench 75.

In this embodiment, the interlayer insulating film 40 includes the plurality of contact openings 43 (not shown) that expose the both end portions (the embedded electrodes 77) of the plurality of gate structures 35 and the single contact opening 43 that exposes inner portions (the embedded insulators 80) of the plurality of gate structures 35, the plurality of source regions 33, and the plurality of contact regions 34 altogether.

The gate pad 45 described above, the plurality of gate wirings 46 described above, and the drain pad 48 described above have the same configuration as in the case of the first configuration example. The source pad 47 described above enters into the single contact opening 43 from above the interlayer insulating film 40 and, inside the single contact opening 43, covers the inner portions (the embedded insulators 80) of the plurality of gate structures 35, the plurality of source regions 33, and the plurality of contact regions 34 altogether.

The source pad 47 is electrically insulated from the plurality of gate structures 35 (the embedded electrodes 77) by the embedded insulators 80, and is electrically connected to the plurality of source regions 33 and the plurality of contact regions 34 at the first principal surface 3 (the active surface 71). The source pad 47 has embedded portions that are embedded in the trenches 75. Inside the trenches 75, the embedded portions of the source pad 47 face the embedded electrodes 77 with the embedded insulators 80 interposed therebetween and are electrically connected to the plurality of source regions 33 and the plurality of contact regions 34 at the opening ends of the trenches 75.

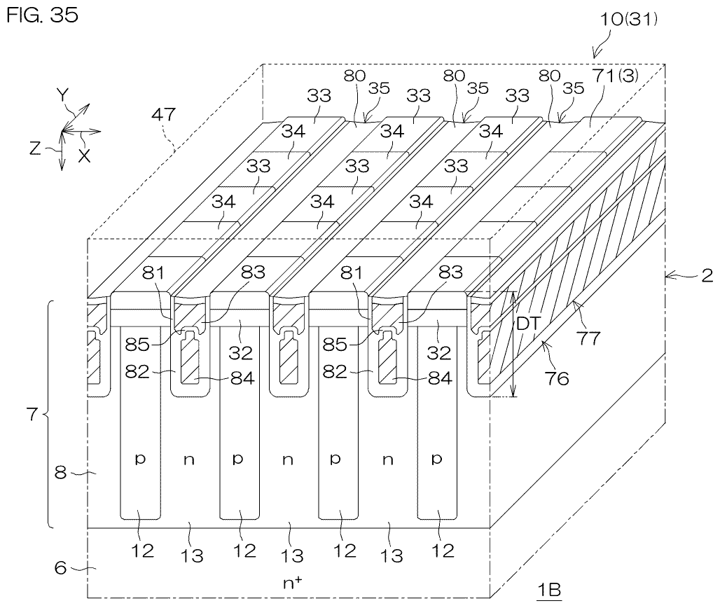

FIG. 35 is a sectional perspective view showing the gate structure 35 according to the fourth configuration example. Referring to FIG. 35, each of the plurality of gate structures 35 according to the fourth configuration example has an arrangement obtained by modifying the plurality of gate structures 35 according to the third configuration example. The arrangement of the gate structure 35 according to the fourth configuration example is also applicable to the arrangements of the gate structures 35 according to the first to third configuration examples.

The plurality of gate structures 35 each include the trench 75, the insulating film 76, the embedded electrode 77, and the embedded insulator 80. The trench 75 has the same configuration as in the case of the first configuration example. In this embodiment, the insulating film 76 includes an upper insulating film 81 and a lower insulating film 82.

The upper insulating film 81 is formed as an insulating film for channel control, and covers the wall surfaces on the opening side of the trench 75 with respect to the bottom portion of the body region 32. The upper insulating film 81 has a portion covering the first pillar region 13 across a boundary portion between the first pillar region 13 and the body region 32. In this case, the covering area of the upper insulating film 81 with respect to the body region 32 is preferably greater than the covering area of the upper insulating film 81 with respect to the first pillar region 13.

The upper insulating film 81 may include a silicon oxide film. The upper insulating film 81 preferably includes a silicon oxide film that consists of the oxide of the chip 2. The upper insulating film 81 may have a thickness of not less than 1 nm and not more than 100 nm. The thickness of the upper insulating film 81 may have a value belonging to any one range among not less than 1 nm and not more than 25 nm, exceeding 25 nm and not more than 50 nm, exceeding 50 nm and not more than 75 nm, and exceeding 75 nm and not more than 100 nm.

The lower insulating film 82 covers the wall surfaces on the bottom wall side of the trench 75 with respect to the bottom portion of the body region 32. The lower insulating film 82 covers the first pillar region 13. The covering area of the lower insulating film 82 with respect to the first pillar region 13 is greater than the covering area of the upper insulating film 81 with respect to the body region 32.

The lower insulating film 82 may include a silicon oxide film. The lower insulating film 82 may include a silicon oxide film that consists of the oxide of the chip 2 or may include a silicon oxide film that is formed by a CVD method. The lower insulating film 82 has a thickness greater than the thickness of the upper insulating film 81. The thickness of the lower insulating film 82 is preferably not less than 10 times and not more than 50 times the thickness of the upper insulating film 81.

The lower insulating film 82 may have a thickness of not less than 100 nm and not more than 500 nm. The thickness of the lower insulating film 82 may have a value belonging to any one range among not less than 100 nm and not more than 150 nm, exceeding 150 nm and not more than 200 nm, exceeding 200 nm and not more than 250 nm, exceeding 250 nm and not more than 300 nm, exceeding 300 nm and not more than 350 nm, exceeding 350 nm and not more than 400 nm, exceeding 400 nm and not more than 450 nm, and exceeding 450 nm and not more than 500 nm.

In this embodiment, the embedded electrode 77 has a multi-electrode structure (double electrode structure) that includes an upper electrode 83, a lower electrode 84, and an intermediate insulating film 85. The upper electrode 83 is embedded at the opening side of the trench 75 with the insulating film 76 interposed therebetween. Specifically, the upper electrode 83 is embedded in the opening side of the trench 75 with the upper insulating film 81 interposed therebetween, and faces the body region 32 with the upper insulating film 81 interposed therebetween.

The facing area of the upper electrode 83 with respect to the body region 32 is greater than the facing area of the upper electrode 83 with respect to the first pillar region 13. In this embodiment, the upper electrode 83 is embedded in the trench 75 at an interval to the bottom wall side of the trench 75 from the first principal surface 3 (the active surface 71) and, at the opening end of the trench 75, demarcates an opening recess that is recessed toward the bottom wall of the trench 75. The upper electrode 83 exposes the surface layer portion of the first principal surface 3 (the active surface 71) and an upper end portion of the upper insulating film 81 at the opening end of the trench 75.

The gate potential is applied as the control potential to the upper electrode 83. The upper electrode 83 controls the inversion and the non-inversion of the channels (the current paths) inside the body region 32 in response to the gate potential. The upper electrode 83 may contain a conductive polysilicon of the p-type or the n-type.

The lower electrode 84 is embedded at the bottom wall side of the trench 75 with the insulating film 76 interposed therebetween. Specifically, the lower electrode 84 is embedded at the bottom wall side of the trench 75 with the lower insulating film 82 interposed therebetween, and faces the first pillar region 13 with the lower insulating film 82 interposed therebetween. That is, the lower electrode 84 is embedded at the bottom wall side of the trench 75 with respect to the bottom portion of the body region 32. Although specific illustration is omitted, the lower electrode 84 is led out to the opening side of the trench 75 at a portion (in this embodiment, at both end portions) of the trench 75.

The facing area of the lower electrode 84 with respect to the first pillar region 13 is greater than the facing area of the upper electrode 83 with respect to the body region 32. The lower electrode 84 extends in a wall shape along a depth direction of the trench 75. The lower electrode 84 has an upper end portion that projects to the upper electrode 83 side from the lower insulating film 82, and is engaged with a lower end portion of the upper electrode 83. The upper end portion of the lower electrode 84 faces the upper insulating film 81 (the body region 32) with the lower end portion of the upper electrode 83 interposed therebetween in the horizontal directions.

The gate potential or the source potential may be applied to the lower electrode 84. When the gate potential is applied to the lower electrode 84, the lower electrode 84 becomes equipotential with the upper electrode 83. A voltage drop between the upper electrode 83 and the lower electrode 84 is thus suppressed. Electric field concentration with respect to the gate structure 35 is thereby suppressed.

On the other hand, when the source potential is applied to the lower electrode 84, the lower electrode 84 can be made to act as a field electrode. A parasitic capacitance between the lower electrode 84 (the field electrode) and the first pillar region 13 is thereby decreased. Decrease in switching speed due to the parasitic capacitance is thereby suppressed. The lower electrode 84 may contain a conductive polysilicon of the p-type or the n-type.

The intermediate insulating film 85 is interposed between the upper electrode 83 and the lower electrode 84 and electrically insulates the upper electrode 83 and the lower electrode 84 inside the trench 75. The intermediate insulating film 85 is continuous to the upper insulating film 81 and the lower insulating film 82. The intermediate insulating film 85 has a smaller thickness than the thickness of the lower insulating film 82. The thickness of the intermediate insulating film 85 is preferably greater than the thickness of the upper insulating film 81. The intermediate insulating film 85 may include a silicon oxide film. The intermediate insulating film 85 preferably includes a silicon oxide film that consists of an oxide of the lower electrode 84.

The embedded insulator 80 is embedded in the trench 75 (the opening recess) such as to expose the first principal surface 3 (the active surface 71) and covers the upper insulating film 81 and the upper electrode 83 inside the recess. The embedded insulator 80 is embedded in the trench 75 at an interval to the upper electrode 83 side from the first principal surface 3 (the active surface 71) and exposes the surface layer portion of the first principal surface 3 (the active surface 71) at the opening end of the trench 75.

In this embodiment, the plurality of source regions 33 described above have portions exposed from the side walls of the trenches 75 at the opening ends of the trenches 75 and face the upper electrodes 83 and the embedded insulators 80 with the upper insulating films 81 interposed therebetween. In this embodiment, the plurality of contact regions 34 described above have portions exposed from the side walls of the trenches 75 at the opening ends of the trenches 75 and face the upper electrodes 83 and the embedded insulators 80 with the upper insulating films 81 interposed therebetween.

The plurality of field regions 38 described above, the interlayer insulating film 40, the gate pad 45, the plurality of gate wirings 46 described above, the source pad 47 described above, and the drain pad 48 described above have the same configurations as those of the second configuration example. In this embodiment, the plurality of gate wirings 46 penetrate through the interlayer insulating film 40 through the plurality of contact openings 43 and are electrically connected to the plurality of upper electrodes 83. In a case where the gate potential is applied to the lower electrodes 84, the plurality of gate wirings 46 penetrate through the interlayer insulating film 40 through the plurality of contact openings 43 and are electrically connected to the plurality of upper electrodes 83 and the plurality of lower electrodes 84.

In a case where the source potential is applied to the lower electrodes 84, the source pad 47 is electrically connected to the plurality of lower electrodes 84. In this case, the semiconductor device 1B may include a source wiring that is led out onto the interlayer insulating film 40 from the source pad 47. In this case, the source wiring is formed in a line shape extending along the peripheral edges of the active surface 71 such as to intersect (specifically, be orthogonal to) portions (one end portions or both end portions) of the plurality of gate structures 35 in a region further outward than the plurality of gate wirings 46. The source wiring penetrates through the interlayer insulating film 40 through the plurality of contact openings 43 and is electrically connected to the plurality of lower electrodes 84.

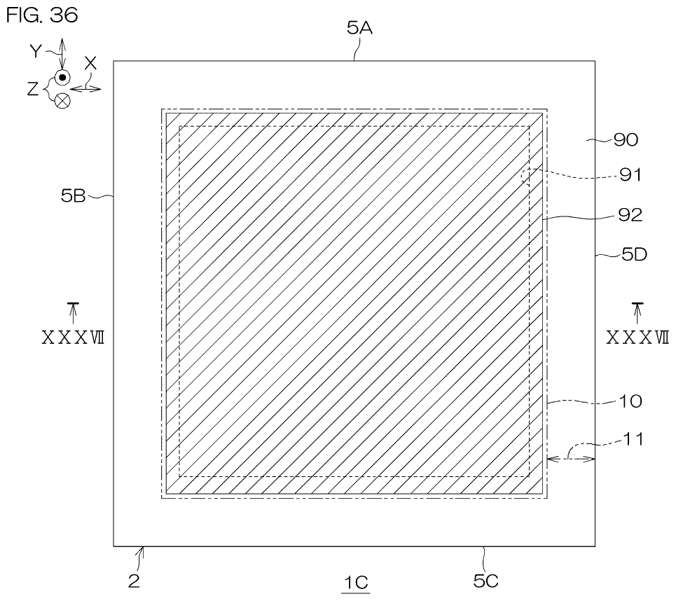

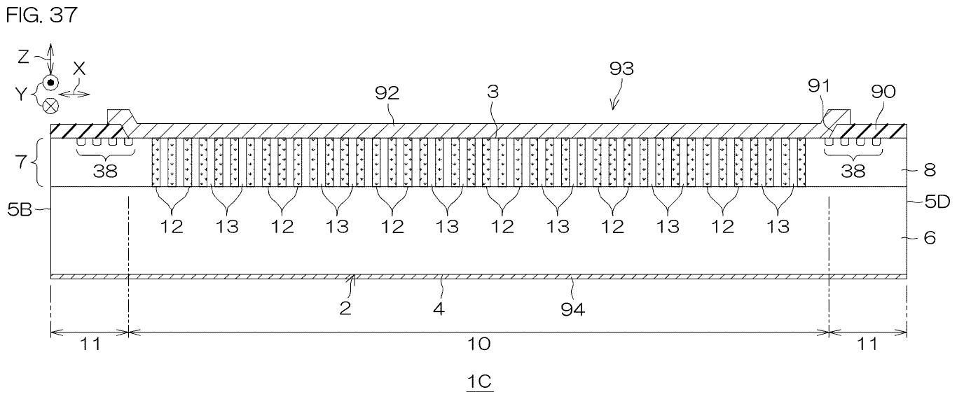

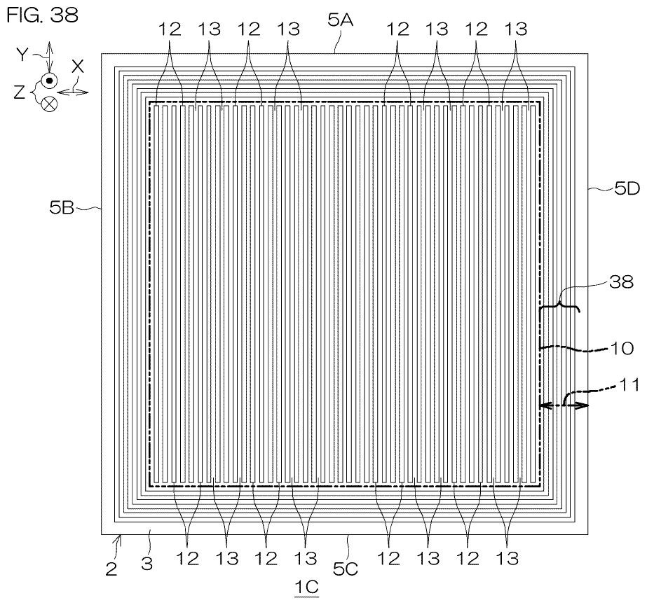

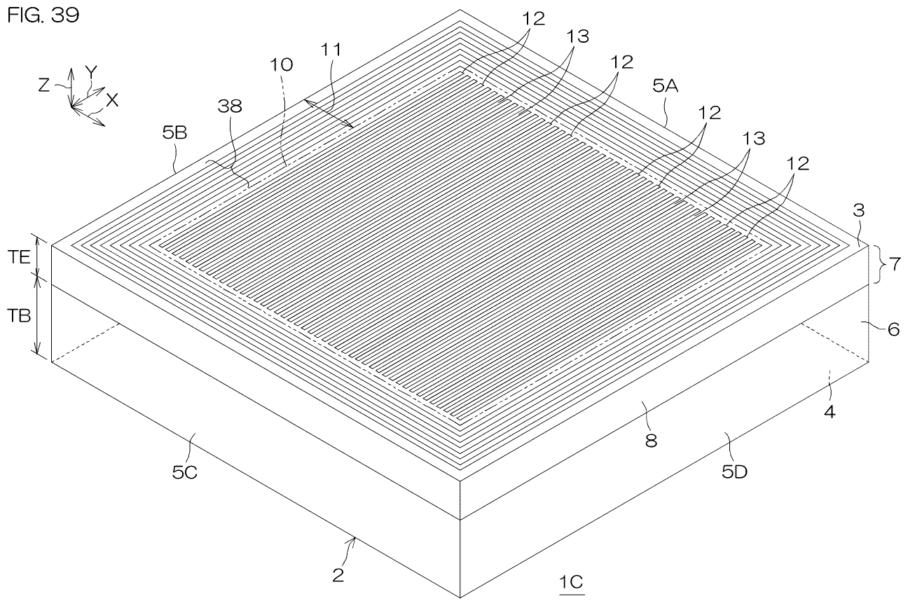

FIG. 36 is a plan view showing a semiconductor device 1C according to a third preferred embodiment. FIG. 37 is a sectional view taken along line XXXVII-XXXVII shown in FIG. 36. FIG. 38 is a plan view showing the layout example of the chip 2. FIG. 39 is a perspective view showing the layout example of the chip 2.

Referring to FIGS. 36 to 39, the semiconductor device 1C includes the chip 2, the base layer 6, the laminated portion 7, the active region 10, the outer peripheral region 11, the plurality of second pillar regions 12, the plurality of first pillar regions 13, and the plurality of field regions 38 as in the case of the semiconductor device 1A. The plurality of second pillar regions 12 may have at least one of the plurality of features shown in the basic embodiment and the first to eleventh configuration examples described above. The plurality of second pillar regions 12 may have a feature in which a plurality of (not less than two) features shown in the basic embodiment and the first to eleventh configuration examples described above are combined.

The semiconductor device 1C includes an interlayer insulating film 90 that selectively covers the first principal surface 3. The interlayer insulating film 90 may have a single layer structure or a laminated structure that includes at least one among a silicon oxide film, a silicon nitride film, and a silicon oxynitride film. In this embodiment, the interlayer insulating film 90 has a single layer structure that includes a silicon oxide film.

The interlayer insulating film 90 covers the plurality of field regions 38 in the outer peripheral region 11. In this embodiment, the interlayer insulating film 90 is continuous to the peripheral edges (the first to fourth side surfaces 5A to 5D) of the first principal surface 3. As a matter of course, the interlayer insulating film 90 may be formed at an interval inward from the peripheral edges of the first principal surface 3 and expose the laminated portion 7 from the peripheral edge portions of the first principal surface 3.

The interlayer insulating film 90 has a contact opening 91 that exposes the active region 10. In this embodiment, the contact opening 91 has an opening wall surface positioned on the innermost field region 38 and exposes the entirety of the active region 10 and an inner edge portion of the innermost field region 38.

The semiconductor device 1C includes a first pad electrode 92 that covers the first principal surface 3 in the active region 10. The first pad electrode 92 is formed as an anode pad. The first pad electrode 92 is disposed at an interval inward from the peripheral edges of the chip 2. The first pad electrode 92 is formed in a polygonal shape (in this embodiment, a quadrilateral shape) along the peripheral edges of the chip 2 in plan view.

The first pad electrode 92 enters into the contact opening 91 from above the interlayer insulating film 90, and is electrically connected to the first principal surface 3 and the innermost field region 38 inside the contact opening 91. The first pad electrode 92 forms a Schottky junction with the first principal surface 3 (the first pillar region 13). An SBD structure 93 (Schottky barrier diode structure) as a diode structure (device structure) is thereby formed in the active region 10.

The semiconductor device 1C includes a second pad electrode 94 that covers the second principal surface 4. The second pad electrode 94 is formed as a cathode pad. The second pad electrode 94 forms an ohmic contact with the base layer 6 exposed from the second principal surface 4. That is, the second pad electrode 94 is electrically connected to the first pillar region 13 through the base layer 6.

The second pad electrode 94 may cover the entirety of the second principal surface 4 such as to be continuous to the peripheral edges (the first to fourth side surfaces 5A to 5D) of the chip 2. The second pad electrode 94 may cover the second principal surface 4 at an interval inward from the peripheral edges of the chip 2 such as to expose the peripheral edge portions of the chip 2.

A breakdown voltage applicable between the first pad electrode 92 and the second pad electrode 94 (between the first principal surface 3 and the second principal surface 4) may be not less than 500 V and not more than 3000 V. The breakdown voltage may have a value belonging to any one range among not less than 500 V and not more than 1000 V, exceeding 1000 V and not more than 1500 V, exceeding 1500 V and not more than 2000 V, exceeding 2000 V and not more than 2500 V, and exceeding 2500 V and not more than 3000 V.

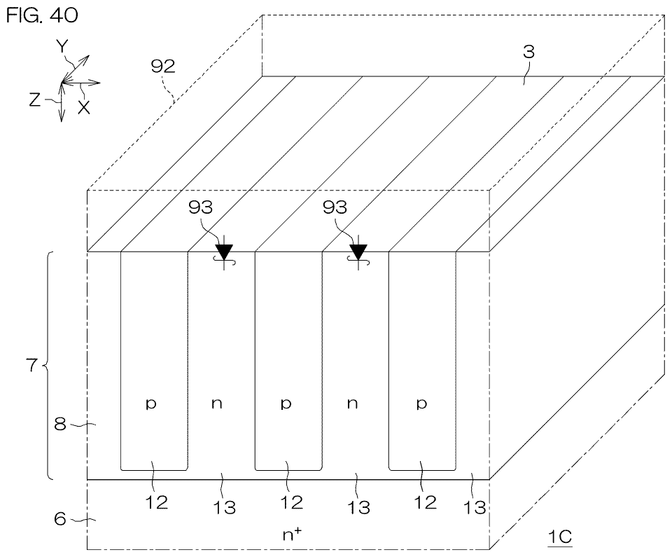

Hereinafter, referring to FIG. 40, a basic embodiment of the SBD structure 93 is shown. FIG. 40 is a sectional perspective view showing the SBD structure 93 according to the basic embodiment. Referring to FIG. 40, when the plurality of second pillar regions 12 and the plurality of first pillar regions 13 are exposed from the first principal surface 3, the first pad electrode 92 is mechanically and electrically connected to the plurality of second pillar regions 12 and the plurality of first pillar regions 13 in the first principal surface 3. In this case, the first pad electrode 92 forms a JBS structure (junction barrier controlled Schottky structure) with the plurality of second pillar regions 12, and forms a Schottky junction with the plurality of first pillar regions 13.

The embodiment described above can be implemented in yet other modes. For example, in each of the preferred embodiments described above, the base layer 6 and the laminated portion 7 each containing an SiC monocrystal are adopted. However, at least one or all of the base layer 6 and the laminated portion 7 may contain a monocrystal of a wide bandgap semiconductor other than the SiC monocrystal.

The wide bandgap semiconductor is a semiconductor that has a greater bandgap than the bandgap of silicon. As examples of a monocrystal of a wide bandgap semiconductor, silicon carbide (SiC), gallium nitride (GaN), diamond (C), gallium oxide (Ga₂O₃), etc., can be cited. The base layer 6 and the laminated portion 7 may be constituted of monocrystals of the same type or may be constituted of monocrystals of different types.

In each of the preferred embodiments described above, an example in which the MIS structure 31 and the SBD structure 93 are individually formed in the different chips 2 is shown. However, the MIS structure 31 and the SBD structure 93 may be formed in the single chip 2. In this case, the SBD structure 93 may be electrically interposed between the source pad 47 (the anode pad) and the drain pad 48 (the cathode pad) as free wheeling diodes with respect to the MIS structure 31.

In each of the preferred embodiments described above, the base layer 6 of the n-type is shown. However, the base layer 6 of the p-type may be adopted instead. In this case, an IGBT (insulated gate bipolar transistor) structure is formed in place of the MISFET structure. In this case, in the above descriptions, the “source” of the MISFET structure is replaced with an “emitter” of the IGBT structure and the “drain” of the MISFET structure is replaced with a “collector” of the IGBT structure. The base layer 6 of the p-type may be a p-type region that contains a trivalent element introduced into a surface layer portion of the second principal surface 4 of the chip 2 by an ion implantation method.

Hereinafter, examples of features extracted from this Description and the attached drawings shall be described. Hereinafter, the alphanumeric characters and the like in parentheses represent the corresponding components and the like in each of the preferred embodiments described above, but are not intended to limit the scope of each clause to the preferred embodiments. The “semiconductor device” in the following clauses may be replaced with a “semiconductor device,” a “wide bandgap semiconductor device,” a “semiconductor switching device,” a “semiconductor rectifier,” a “MISFET device,” an “IGBT device,” a “diode device,” or the like as necessary.
[Clause 1-1]

A semiconductor device (1A, 1B, 1C) including:
a semiconductor layer (7) of a first conductivity type that has a first principal surface (3) and a second principal surface (4);
a first pillar region (13) of the first conductivity type that extends in a depth direction (Z) of the semiconductor layer (7) from the first principal surface (3) toward the second principal surface (4) inside the semiconductor layer (7); and
a second pillar region (12) of a second conductivity type that is adjacent to the first pillar region (13) inside the semiconductor layer (7) and extends in the depth direction (Z),
in which in the depth direction (Z), a maximum value of a profile (22, 23) of a background impurity concentration of the first conductivity type of the second pillar region (12) is not more than ½ of a maximum value of a profile (20, 21) of a first impurity concentration of the first conductivity type of the first pillar region (13).

According to this arrangement, the maximum value of the background impurity concentration of the first conductivity type of the second pillar region (12) is small. Even if the background impurity concentration varies in the depth direction (Z) of the semiconductor layer (7), an influence of the variation on an effective impurity concentration of the second conductivity type in the second pillar region (12) can thereby be reduced. Therefore, the effective impurity concentration of the second conductivity type in the second pillar region (12) can be stabilized. As a result, the influence on a charge balance between the first pillar region (13) and the second pillar region (12) can be reduced, and thus, it is possible to suppress fluctuation in a withstand voltage caused by collapse of the charge balance (charge imbalance).
[Clause 1-2]

The semiconductor device (1A, 1B, 1C) according to Clause 1-1, in which the maximum value of the profile (22, 23) of the background impurity concentration is smaller than the maximum value of the profile (20, 21) of the first impurity concentration by at least one order of magnitude.
[Clause 1-3]

The semiconductor device (1A, 1B, 1C) according to Clause 1-1 or 1-2, in which the first impurity concentration is adjusted by a first element, and
the second pillar region (12) does not contain the first element, and the background impurity concentration is adjusted by a second element that is different from the first element.
[Clause 1-4]

The semiconductor device (1A, 1B, 1C) according to Clause 1-3, in which the first element and the second element are constituted of trivalent elements that are different from each other.
[Clause 1-5]

The semiconductor device (1A, 1B, 1C) according to Clause 1-4, in which the first element is phosphorus (P) and the second element is nitrogen (N).
[Clause 1-6]

The semiconductor device (1A, 1B, 1C) according to Clause 1-1 or 1-2, in which the profile (22, 23) of the background impurity concentration is a profile at a central position in a width direction of the second pillar region (12).
[Clause 1-7]

The semiconductor device (1A, 1B, 1C) according to Clause 1-1 or 1-2, in which the second pillar region (12) has a thickness (T2) of not less than 1 μm and not more than 30 μm.

According to this arrangement, since the second pillar region (12) is formed up to a comparatively deep position of the semiconductor layer (7), the withstand voltage can be improved.
[Clause 1-8]

The semiconductor device (1A, 1B, 1C) according to Clause 1-1 or 1-2, in which the first pillar region (13) and the second pillar region (12) have a same width (W1, W2).
[Clause 1-9]

The semiconductor device (1A, 1B, 1C) according to Clause 1-1 or 1-2, in which the semiconductor layer (7) is an SiC semiconductor layer (7).

According to this arrangement, features of the first pillar region (13) and the second pillar region (12) described above can be applied to the power semiconductor device (1A, 1B, 1C) including the SiC semiconductor layer (7).
[Clause 1-10]

A semiconductor device (1A, 1B, 1C) including:
an SiC chip (2) that has a first principal surface (3) and a second principal surface (4);
a drift region (8) of a first conductivity type that is formed in a surface layer portion of the first principal surface (3) of the SiC chip (2);
a super junction structure (SJ) that includes a first pillar region (13) of the first conductivity type and a second pillar region (12) of a second conductivity type alternately and repeatedly aligned adjacent to each other in a direction along the first principal surface (3) inside the drift region (8); and
a device structure (31, 93) that is formed between the super junction structure (SJ) and the first principal surface (3),
in which in a depth direction (Z) of the SiC chip (2), a maximum value of a profile (22, 23) of a background impurity concentration of the first conductivity type of the second pillar region (12) is not more than 1/2 of a maximum value of a profile (20, 21) of a first impurity concentration of the first conductivity type of the first pillar region (13).

According to this arrangement, the maximum value of the background impurity concentration of the first conductivity type of the second pillar region (12) is small. Even if the background impurity concentration varies in the depth direction (Z) of the SiC chip (2), an influence of the variation on an effective impurity concentration of the second conductivity type in the second pillar region (12) can thereby be reduced. Therefore, the effective impurity concentration of the second conductivity type in the second pillar region (12) can be stabilized. As a result, the influence on a charge balance between the first pillar region (13) and the second pillar region (12) can be reduced, and thus, it is possible to suppress fluctuation in a withstand voltage caused by collapse of the charge balance (charge imbalance). Therefore, the withstand voltage performance of the SiC semiconductor device (1A, 1B, 1C) can be further improved by the super junction structure (SJ).
[Clause 1-11]

The semiconductor device (1A, 1B, 1C) according to Clause 1-10, in which the drift region (8) has a drift impurity concentration of the first conductivity type,
a maximum value of the profile (22, 23) of the drift impurity concentration in the depth direction (Z) is smaller than the maximum value of the profile (20, 21) of the first impurity concentration by at least one order of magnitude, and
the profile (22, 23) of the background impurity concentration and the profile (22, 23) of the drift impurity concentration are equal to or approximate to each other.

For example, when the drift region (8) is formed by epitaxial growth, a raw material gas of the drift region (8) is supplied while impurity ions are added in the crystal growth process. Since the impurity distribution in the epitaxial layer (the drift region (8)) can be easily controlled, for example, the drift impurity concentration can be made fixed or substantially fixed in the depth direction (Z) of the epitaxial layer. Since the background impurity concentration can also thereby be made fixed or substantially fixed, it is possible to effectively reduce the variation in the depth direction (Z) of the effective impurity concentration of the second conductivity type in the second pillar region (12). As a result, it is possible to further suppress the fluctuation in the withstand voltage caused by the charge imbalance of the super junction structure (SJ).
[Clause 1-12]

The semiconductor device (1A, 1B, 1C) according to Clause 1-11, in which when the first impurity concentration of the first pillar region (13) is N1, a width of the first pillar region (13) is W1, a second impurity concentration of the second conductivity type of the second pillar region (12) is N2, and the width of the second pillar region (12) is W2 a charge balance CB between the first pillar region (13) and the second pillar region (12) is represented by the following formula (1), and
the charge balance CB is within a range of not less than 0.9 and not more than 1.1 in a section from an apex portion to a bottom portion in the depth direction (Z) of the super junction structure (SJ).

CB=(N1×W1)/(N2×W2) . . . (1)

According to this arrangement, the charge balance of the super junction structure (SJ) is kept within the range of not less than 0.9 and not more than 1.1 in the section from the apex portion to the bottom portion in the depth direction (Z). Since a variation range of the charge balance is narrow, the withstand voltage due to the super junction structure (SJ) can be stably secured.
[Clause 1-13]

The semiconductor device (1A, 1B, 1C) according to Clause 1-12, in which the width W1 of the first pillar region (13) and the width W2 of the second pillar region (12) are equal to each other.

As described above, the charge balance of the super junction structure (SJ) is kept within the range of not less than 0.9 and not more than 1.1 in the section from the apex portion to the bottom portion in the depth direction (Z). The width W1 of the first pillar region (13) and the width W2 of the second pillar region (12) can thereby be made equal to each other. As a result, it is not necessary to narrow or widen only the width of one of the first pillar region (13) and the second pillar region (12). Therefore, since the super junction structure (SJ) can be formed at high density, the withstand voltage can be further improved.
[Clause 1-14]

The semiconductor device (1A, 1B, 1C) according to Clause 1-12, in which the second pillar region (12) has a thickness (T2) of not less than 1 μm and not more than 30 μm.

According to this arrangement, since the super junction structure (SJ) is formed up to a comparatively deep position of the SiC chip (2), the withstand voltage can be improved.
[Clause 1-15]

The semiconductor device (1A, 1B, 1C) according to any one of Clauses 1-11 to 1-14, in which the first impurity concentration is adjusted by phosphorus (P), and
the second pillar region (12) does not contain phosphorus (P), and the drift impurity concentration is adjusted by nitrogen (N).
[Clause 1-16]

The semiconductor device (1A, 1B, 1C) according to any one of Clauses 1-11 to 1-15, in which the SiC chip (2) includes a base SiC layer (6) and an SiC layer laminated on the base SiC layer (6), and
the second pillar region (12) includes a lower end portion (12a) that coincides with a lower end of the SiC layer and is connected to the base SiC layer (6) and an upper end portion (12b) that coincides with an upper end of the SiC layer.
[Clause 1-17]

The semiconductor device (1A, 1B, 1C) according to any one of Clauses 1-11 to 1-15, in which the SiC chip (2) includes a base SiC layer (6) and an SiC layer (7) laminated on the base SiC layer (6), and
the second pillar region (12) includes a lower end portion (12a) that coincides with a lower end of the SiC layer (7) and is connected to the base SiC layer (6), and an upper end portion (12b) that is formed at an interval to the lower end side from an upper end of the SiC layer and faces the first principal surface (3) with a portion of the SiC layer (7) interposed therebetween.
[Clause 1-18]

The semiconductor device (1A, 1B, 1C) according to any one of Clauses 1-11 to 1-15, in which the SiC chip (2) includes a base SiC layer (6) and an SiC layer (7) laminated on the base SiC layer (6), and
the second pillar region (12) includes a lower end portion (12a) that is formed at an interval to an upper end side from a lower end of the SiC layer (7) and faces the base SiC layer (6) with a portion of the SiC layer (7) interposed therebetween, and an upper end portion (12b) that coincides with the upper end of the SiC layer (7).
[Clause 1-19]

The semiconductor device (1A, 1B, 1C) according to any one of Clauses 1-11 to 1-15, in which the SiC chip (2) includes a base SiC layer (6) and an SiC layer (7) laminated on the base SiC layer (6), and
the second pillar region (12) includes a lower end portion (12a) that is formed at an interval to an upper end side from a lower end of the SiC layer and faces the base SiC layer (6) with a portion of the SiC layer (7) interposed therebetween, and an upper end portion (12b) that is formed at an interval to the lower end side from the upper end of the SiC layer (7) and faces the first principal surface (3) with a portion of the SiC layer (7) interposed therebetween.
[Clause 1-20]

The semiconductor device (1A, 1B, 1C) according to any one of Clauses 1-16 to 1-19, in which the second pillar region (12) has a laminated structure that includes a first region (18) and a second region (19) in a thickness direction (Z) of the SiC layer (7), and
the first region (18) and the second region (19) are disposed at an interval from each other in the thickness direction (Z) of the SiC layer (7) and face each other with a portion (25) of the SiC layer (7) interposed therebetween.
[Clause 1-21]

The semiconductor device (1A, 1B, 1C) according to any one of Clauses 1-16 to 1-19, in which the second pillar region (12) has a laminated structure that includes a first region (18) and a second region (19) in a thickness direction (Z) of the SiC layer (7), and
the first region (18) and the second region (19) are connected to each other in the thickness direction (Z) of the SiC layer (7).
[Clause 1-22]

The semiconductor device (1A, 1B) according to any one of Clauses 1-16 to 1-21, in which the device structure (31, 93) includes a field effect transistor structure (31) having a body region (32) of the second conductivity type that is formed in the surface layer portion of the first principal surface (3) and overlaps the second pillar region (12) in the thickness direction (Z) of the SiC layer (7), a source region (33) of the first conductivity type that is formed in a surface layer portion of the body region (32), and a gate structure (35) that overlaps the body region (32).
[Clause 1-23]

The semiconductor device (1A, 1B) according to Clause 1-22, in which the gate structure (35) includes a planar gate structure.
[Clause 1-24]

The semiconductor device (1A, 1B) according to Clause 1-22, in which the gate structure (35) includes a trench gate structure.
[Clause 1-25]

The semiconductor device (1C) according to any one of Clauses 1-16 to 1-21, in which the device structure (31, 93) includes a diode structure (93) that is formed by a first electrode (92) formed on the first principal surface (3) and electrically connected to the first pillar region (13) and the first pillar region (13).
[Clause 2-1]

A semiconductor device (1A, 1B, 1C) including:
a chip (2) that has a first principal surface (3) and a second principal surface (4);
a drift region (8) of an n-type that is formed in a surface layer portion of the first principal surface (3) of the chip (2);
a plurality of pillar regions (12) of a p-type that are disposed inside the drift region (8) and extend in a thickness direction (Z) of the chip (2); and
a second drift region (13) of the n-type that is sandwiched between the plurality of pillar regions (12) and has a higher impurity concentration than the drift region (8),
in which concentration of the drift region (8) is adjusted by nitrogen (N),
the concentration of the second drift region (13) is adjusted by phosphorus (P), and
an n-type background concentration in the pillar region (12) is lower than the n-type impurity concentration of the second drift region (13).
[Clause 2-2]

The semiconductor device (1A, 1B, 1C) according to Clause 2-1, in which when a donor concentration of the second drift region (13) is Nd, an acceptor concentration of the pillar region (12) is Na, and a background donor concentration of the pillar region (12) is Ndb,
an effective acceptor concentration (Na−Ndb) of the pillar region (12) represented by a difference between the acceptor concentration Na and the background donor concentration Ndb is not less than 90% and not more than 110% of the donor concentration Nd.
[Clause 2-3]

The semiconductor device (1A, 1B, 1C) according to Clause 2-2, in which a maximum value of the donor concentration Nd in the thickness direction (Z) of the chip (2) is not less than 1×10¹⁶ cm⁻³ and not more than 1×10¹⁸ cm⁻³, and
a maximum value of the effective acceptor concentration (Na−Ndb) in the thickness direction (Z) of the chip (2) is not less than 1×10¹⁶ cm⁻³ and not more than 1×10¹⁸ cm⁻³.
[Clause 2-4]

The semiconductor device (1A, 1B, 1C) according to Clause 2-2 or 2-3, in which the background donor concentration in the thickness direction (Z) of the chip (2) is not less than 1×10¹⁵ cm⁻³ and not more than 1×10¹⁶ cm⁻³.
[Clause 2-5]

The semiconductor device (1A, 1B, 1C) according to any one of Clauses 2-2 to 2-4, in which when a width of the second drift region (13) is W1 and the width of the pillar region (12) is W2, a charge balance CB between the second drift region (13) and the pillar region (12) is represented by the following formula (1), and
the charge balance CB is within a range of not less than 0.9 and not more than 1.1 in a section from an apex portion to a bottom portion in a depth direction (Z) of the pillar region (12).

CB=(Nd×W1)/(Na×W2) . . . (1)

1. A semiconductor device comprising:
a semiconductor layer of a first conductivity type that has a first principal surface and a second principal surface;
a first pillar region of the first conductivity type that extends in a depth direction of the semiconductor layer from the first principal surface toward the second principal surface inside the semiconductor layer; and
a second pillar region of a second conductivity type that is adjacent to the first pillar region inside the semiconductor layer and extends in the depth direction,
wherein in the depth direction, a maximum value of a profile of a background impurity concentration of the first conductivity type of the second pillar region is not more than ½ of a maximum value of a profile of a first impurity concentration of the first conductivity type of the first pillar region.

2. The semiconductor device according to claim 1, wherein the maximum value of the profile of the background impurity concentration is smaller than the maximum value of the profile of the first impurity concentration by at least one order of magnitude.

3. The semiconductor device according to claim 1, wherein the first impurity concentration is adjusted by a first element, and
the second pillar region does not contain the first element, and the background impurity concentration is adjusted by a second element that is different from the first element.

4. The semiconductor device according to claim 3, wherein the first element and the second element are constituted of trivalent elements that are different from each other.

5. The semiconductor device according to claim 4, wherein the first element is phosphorus (P) and the second element is nitrogen (N).

6. The semiconductor device according to claim 1, wherein the profile of the background impurity concentration is a profile at a central position in a width direction of the second pillar region.

7. The semiconductor device according to claim 1, wherein the second pillar region has a thickness of not less than 1 μm and not more than 30 μm.

8. The semiconductor device according to claim 1, wherein the first pillar region and the second pillar region have a same width.

9. The semiconductor device according to claim 1, wherein the semiconductor layer is an SiC semiconductor layer.

10. A semiconductor device comprising:
an SiC chip that has a first principal surface and a second principal surface;
a drift region of a first conductivity type that is formed in a surface layer portion of the first principal surface of the SiC chip;
a super junction structure that includes a first pillar region of the first conductivity type and a second pillar region of a second conductivity type alternately and repeatedly aligned adjacent to each other in a direction along the first principal surface inside the drift region; and
a device structure that is formed between the super junction structure and the first principal surface,
wherein in a depth direction of the SiC chip, a maximum value of a profile of a background impurity concentration of the first conductivity type of the second pillar region is not more than ½ of a maximum value of a profile of a first impurity concentration of the first conductivity type of the first pillar region.

11. The semiconductor device according to claim 10, wherein the drift region has a drift impurity concentration of the first conductivity type,
a maximum value of the profile of the drift impurity concentration in the depth direction is smaller than the maximum value of the profile of the first impurity concentration by at least one order of magnitude, and
the profile of the background impurity concentration and the profile of the drift impurity concentration are equal to or approximate to each other.

12. The semiconductor device according to claim 11, wherein when the first impurity concentration of the first pillar region is N1, a width of the first pillar region is W1, a second impurity concentration of the second conductivity type of the second pillar region is N2, and the width of the second pillar region is W2, a charge balance CB between the first pillar region and the second pillar region is represented by the following formula (1), and
the charge balance CB is within a range of not less than 0.9 and not more than 1.1 in a section from an apex portion to a bottom portion in the depth direction of the super junction structure.
CB=(N1×W1)/(N2×W2) . . . (1)

13. The semiconductor device according to claim 12, wherein the width W1 of the first pillar region and the width W2 of the second pillar region are equal to each other.

14. The semiconductor device according to claim 12, wherein the second pillar region has a thickness of not less than 1 μm and not more than 30 μm.

15. The semiconductor device according to claim 11, wherein the first impurity concentration is adjusted by phosphorus (P), and
the second pillar region does not contain phosphorus (P), and the drift impurity concentration is adjusted by nitrogen (N).
